(19) United States
(12) Patent Application Publication
(10) Pub. No.: US 2026/0198186 A1
(43) Pub. Date: Jul. 9, 2026

(54) DISPLAY DEVICE, ELECTRONIC DEVICE USING THE SAME, AND METHOD FOR FABRICATING THE DISPLAY DEVICE

(71) Applicant: Samsung Display Co., LTD., Yongin-si (KR)

(72) Inventors: Hee Jun YANG, Yongin-si (KR); A Rong KIM, Yongin-si (KR); Young Min MOON, Yongin-si (KR); Hee Min PARK, Yongin-si (KR); Sa Min LEE, Yongin-si (KR)

(21) Appl. No.: 19/324,206

(22) Filed: Sep. 10, 2025

(30) Foreign Application Priority Data
Jan. 7, 2025 (KR) 10-2025-0002066

(51) Int. Cl. H10K 59/123; H10K 59/12; H10K 59/121; H10K 59/122; H10K 59/80

(52) U.S. Cl. CPC H10K 59/123; H10K 59/1201; H10K 59/1213; H10K 59/122; H10K 59/80522

(57) ABSTRACT

A display device including a substrate including an emission area and a non-emission area; a bank structure which is disposed on the emission area of the substrate and has an overhang structure and through which an anode contact hole overlapping the emission area penetrates; a connection electrode disposed between the substrate and the bank structure in a portion overlapping the anode contact hole; a first element insulating layer disposed on the bank structure, overlapping the anode contact hole and covering a side surface of the bank structure; an anode electrode disposed on the first element insulating layer; an anode planarization layer disposed between the connection electrode and the anode electrode in a portion overlapping the anode contact hole; and a second element insulating layer covering an edge of the anode electrode, defining an opening, and in contact with the first element insulating layer.

This application claims priority to Korean Patent Application No. 10-2025-0002066, filed on Jan. 7, 2025, and all the benefits accruing therefrom under 35 U.S.C. § 119, the content of which in its entirety is herein incorporated by reference.

### BACKGROUND

### 1. Field

The disclosure relates to a display device, an electronic device using the same, and a method for fabricating the display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device and an organic light-emitting display device. Among the flat panel display devices, in the light-emitting display device, since each of pixels of a display panel includes a light-emitting element capable of emitting light by itself, an image may be displayed without a backlight unit providing light to the display panel.

### SUMMARY

Features of the disclosure provide a display device capable of providing a high-resolution image, an electronic device using the same, and a method for fabricating the display device.

Features of the disclosure solve reliability defects of a light-emitting element included in a display device.

However, features of the disclosure are not restricted to those set forth herein. The above and other features of the disclosure will become more apparent to one of ordinary skill in the art to which the disclosure pertains by referencing the detailed description of the disclosure given below.

Other features and embodiments may be apparent from the following detailed description, and the drawings.

In an embodiment of the disclosure, a display device including: a substrate including an emission area and a non-emission area; a bank structure which is disposed on the emission area of the substrate and has an overhang structure and through which an anode contact hole overlapping the emission area penetrates; a connection electrode disposed between the substrate and the bank structure in a portion overlapping the anode contact hole; a first element insulating layer disposed on the bank structure, overlapping the anode contact hole and covering a side surface of the bank structure; an anode electrode disposed on the first element insulating layer; an anode planarization layer disposed between the connection electrode and the anode electrode in a portion overlapping the anode contact hole; and a second element insulating layer covering an edge of the anode electrode, defining an opening, and in contact with the first element insulating layer.

In an embodiment, the bank structure may include a first bank layer; a second bank layer disposed on the first bank layer; and a third bank layer including a tip protruding toward the non-emission area more than a first side surface of the second bank layer, where the anode planarization layer overlaps the anode contact hole and penetrates the first bank layer, the second bank layer, and the third bank layer.

In an embodiment, the anode planarization layer may be spaced apart from the first bank layer, the second bank layer, the third bank layer while the first element insulating layer is interposed between the anode planarization layer and the first to third bank layers.

In an embodiment, the display device may further include a first light-emitting layer disposed on the anode electrode and entirely covering the second element insulating layer; a cathode electrode disposed on the first light-emitting layer; and an auxiliary electrode disposed on the cathode electrode and in contact with the tip of the third bank layer.

In an embodiment, the auxiliary electrode may contact the first side surface of the second bank layer, and in a portion overlapping the non-emission area, the auxiliary electrode is spaced apart from the first bank layer in a direction perpendicular to the substrate.

In an embodiment, the anode planarization layer may contact the anode electrode and the connection electrode, and the anode planarization layer is electrically connected to the anode electrode and the connection electrode.

In an embodiment, the display device may further include a transistor disposed between the substrate and the connection electrode, where the anode electrode is connected to the transistor through the anode planarization layer and the connection electrode.

In an embodiment, the anode planarization layer may completely fill the anode contact hole.

In an embodiment, the anode planarization layer may include or consist of a transparent conductive material.

In an embodiment, the anode planarization layer may include a first surface facing the anode electrode, and the first surface is completely covered by the anode electrode.

In an embodiment, in a plan view, the first element insulating layer may expose the anode planarization layer, and in the plan view, the first element insulating layer completely surrounds the anode planarization layer.

In an embodiment, in the plan view, the bank structure may be spaced apart from the anode planarization layer while the first element insulating layer is interposed between the bank structure and the anode planarization layer, and in the plan view, the bank structure completely surrounds the anode planarization layer.

In an embodiment of the disclosure, a method for fabricating a display device may include defining an anode contact hole penetrating a bank structure and a first element insulating layer; forming an anode planarization layer and an anode electrode; forming a tip of the bank structure after forming a second element insulating layer defining an opening; and forming a light-emitting layer, a cathode electrode, an auxiliary electrode, and an element inorganic layer on the anode electrode.

In an embodiment, in the forming the anode planarization layer and the anode electrode, a part of the anode planarization layer may be removed by performing a chemical mechanical polishing (“CMP”) process, the anode planarization layer includes a first surface in contact with the anode electrode, and the first surface includes a surface polished by the CMP process.

In an embodiment of the disclosure, an electronic device including: a display device including a substrate including an emission area and a non-emission area; and at least one of a display module, a processor, a memory, and a power module connected to the display device, where the display device further includes: a bank structure which is disposed on the emission area of the substrate and has an overhang structure and through which an anode contact hole overlapping the emission area penetrates; a connection electrode disposed between the substrate and the bank structure in a portion overlapping the anode contact hole; a first element insulating layer disposed on the bank structure, overlapping the anode contact hole and covering a side surface of the bank structure; an anode electrode disposed on the first element insulating layer; an anode planarization layer disposed between the connection electrode and the anode electrode in a portion overlapping the anode contact hole; and a second element insulating layer covering an edge of the anode electrode, defining an opening, and in contact with the first element insulating layer.

In an embodiment, the bank structure may include a first bank layer; a second bank layer disposed on the first bank layer; and a third bank layer including a tip protruding toward the non-emission area more than a first side surface of the second bank layer, where the anode planarization layer penetrates the first bank layer, the second bank layer, and the third bank layer while overlapping the anode contact hole.

In an embodiment, the anode planarization layer may be spaced apart from the first bank layer, the second bank layer, the third bank layer while the first element insulating layer is interposed between the anode planarization layer and the first to third bank layers.

In an embodiment, the electronic device may further include a first light-emitting layer disposed on the anode electrode and entirely covering the second element insulating layer; a cathode electrode disposed on the first light-emitting layer; and an auxiliary electrode disposed on the cathode electrode and in contact with the tip of the third bank layer.

In an embodiment, the anode planarization layer may completely fill the anode contact hole.

In an embodiment, the electronic device may further include a transistor disposed between the substrate and the connection electrode, where the anode electrode is connected to the transistor through the anode planarization layer and the connection electrode.

In accordance with the display device, the electronic device using the same, and the method for fabricating the display device in embodiments, it is possible to provide a high-resolution image, and solve reliability defects of a light-emitting element included in the display device.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view showing an embodiment of a display device;

FIG. 2 is a cross-sectional view illustrating an embodiment of a display device;

FIG. 3 is a plan view illustrating an embodiment of a display layer of a display device;

FIG. 4 is a layout diagram illustrating a plurality of pixels arranged in the display area of FIG. 3;

FIG. 5 is a cross-sectional view showing an embodiment of a display layer taken along line A1-A1′ of FIG. 4;

FIG. 6 is an enlarged cross-sectional view of the display element layer overlapping the first emission area in FIG. 5;

FIG. 7 is an enlarged cross-sectional view of area A of FIG. 6;

FIG. 8 is an enlarged plan view of area ‘C’ of FIG. 7;

FIG. 9 is a plan view illustrating the arrangement of the bank structure, the anode planarization layer, and the first element insulating layer in FIG. 7;

FIG. 10 is a flowchart illustrating a method for fabricating the display element layer of FIG. 5;

FIGS. 11 to 13 are cross-sectional views showing operation S100 of FIG. 10;

FIGS. 14 to 17 are cross-sectional views showing operation S200 of FIG. 10;

FIGS. 18 to 21 are cross-sectional views showing operation S300 of FIG. 10;

FIGS. 22 to 25 are cross-sectional views showing operation S400 of FIG. 10;

FIG. 26 is a block diagram of an embodiment of an electronic device; and

FIG. 27 is schematic views of embodiments of electronic devices.

### DETAILED DESCRIPTION

Advantages and features of the disclosure and methods of accomplishing the same may be understood more readily by reference to the following detailed description of embodiments and the accompanying drawings. The disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the disclosure will only be defined by the appended claims.

It will be understood that when an element or layer is referred to as being “on” another element or layer, the element or layer may be directly on another element or layer or intervening elements or layers. Like reference numerals refer to like elements throughout the specification. Shapes, sizes, ratios, angles, numbers, etc. disclosed in the drawings for describing embodiments are merely an example, and the disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the disclosure.

Features of various embodiments of the disclosure may be partially or entirely coupled to or combined with each other, and may be inter-operated and driven in technically various ways. The embodiments may be implemented independently from each other, or may be implemented together in a co-dependent relationship.

Hereinafter, illustrative embodiments will be described with reference to the accompanying drawings.

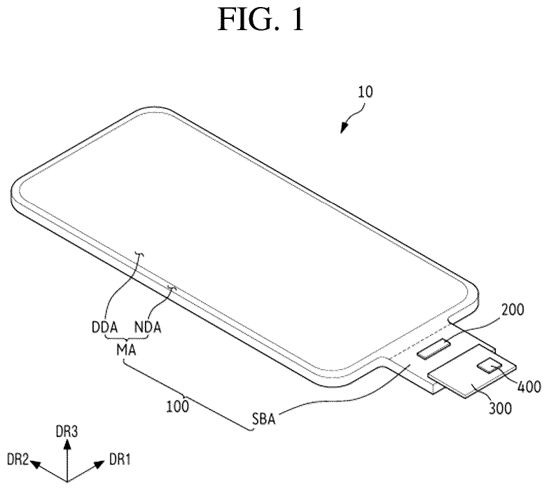

FIG. 1 is a perspective view showing an embodiment of a display device.

Referring to FIG. 1, a display device 10 may be applied to portable electronic devices such as a mobile phone, a smartphone, a tablet personal computer, a mobile communication terminal, an electronic organizer, an electronic book, a portable multimedia player (“PMP”), a navigation system, an ultra mobile personal computer (“UMPC”) or the like. In an embodiment, the display device 10 may be applied as a display unit of a television, a laptop, a monitor, a billboard, or an Internet-of-Things (“IoT”) device, for example. In another embodiment, the display device 10 may be applied to wearable devices such as a smart watch, a watch phone, a glasses type display, or a head mounted display (“HMD”).

The display device 10 may have a planar shape similar to a quadrilateral shape. In an embodiment, the display device 10 may have a planar shape similar to a quadrilateral shape having a short side in a first direction DR1 and a long side in a second direction DR2, for example. A corner where the short side in the first direction DR1 and the long side in the second direction DR2 meet may be right-angled or rounded with a selected curvature. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA. The main region MA may include the display area DDA including pixels displaying an image and the non-display area NDA disposed around the display area DDA.

The display area DDA may emit light from a plurality of openings or a plurality of emission areas to be described later. In an embodiment, the display panel 100 may include a pixel circuit including switching elements, an element insulating layer defining an emission area or an opening, and a self-light-emitting element, for example. In an embodiment, the self-light-emitting element may include at least one of an organic light-emitting diode (“LED”) including an organic light-emitting layer, a quantum dot LED including a quantum dot light-emitting layer, an inorganic LED including an inorganic semiconductor, or a micro LED, for example, but is not limited thereto. In the following drawings, a case where the self-light-emitting element is an organic light-emitting diode is illustrated as one of the embodiments.

The non-display area NDA may be an area outside the display area DDA. The non-display area NDA may be defined as an edge area of the main region MA of the display panel 100.

The sub-region SBA may be a region extending from one side of the main region MA. The sub-region SBA may include a flexible material which may be bent, folded or rolled. In an embodiment, when the sub-region SBA is bent, the sub-region SBA may overlap the main region MA in a thickness direction (e.g., third direction DR3), for example. The sub-region SBA may include the display driver 200 and a pad portion connected to the circuit board 300. In another embodiment, the sub-region SBA may be omitted, and the display driver 200 and the pad portion may be disposed in the non-display area NDA.

The display driver 200 may output signals and voltages for driving the display panel 100. The display driver 200 may be formed as an integrated circuit (“IC”) and disposed (e.g., mounted) on the display panel 100 by a chip on glass (“COG”) method, a chip on plastic (“COP”) method, or an ultrasonic bonding method. In an embodiment, the display driver 200 may be disposed in the sub-region SBA, and may overlap the main region MA in the thickness direction by bending of the sub-region SBA, for example. In another embodiment, the display driver 200 may be disposed (e.g., mounted) on the circuit board 300.

The circuit board 300 may be attached to the pad portion of the display panel 100 by an anisotropic conductive film (“ACF”). The circuit board 300 may be a flexible printed circuit board, a printed circuit board, or a flexible film such as a chip on film.

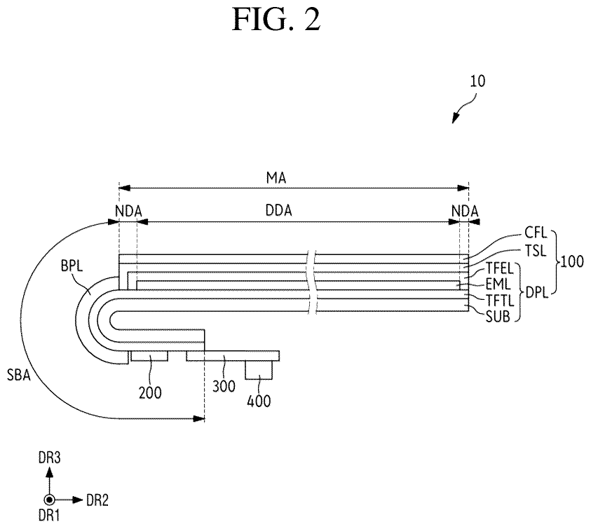

The touch driver 400 may be disposed (e.g., mounted) on the circuit board 300. The touch driver 400 may be connected to a touch sensor layer TSL (refer to FIG. 2) for sensing and driving a touch.

FIG. 2 is a cross-sectional view illustrating an embodiment of a display device.

Referring to FIG. 2, the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate or a base member. The substrate SUB may be a flexible substrate which may be bent, folded or rolled. In an embodiment, the substrate SUB may include a polymer resin such as polyimide (“PI”), for example, but is not limited thereto. In another embodiment, the substrate SUB may include a glass material or a metal material.

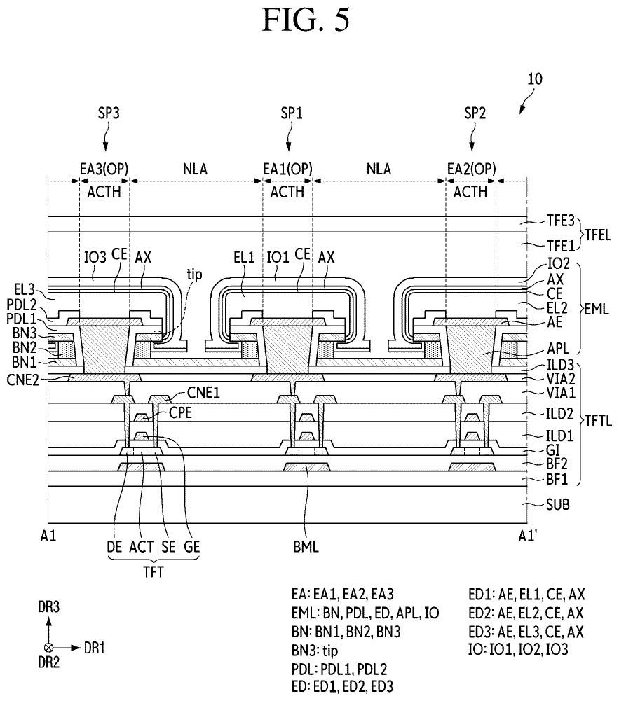

The transistor layer TFTL may be disposed on the substrate SUB. The transistor layer TFTL may be disposed in a portion overlapping the display area DDA, the non-display area NDA, and the sub-region SBA. The transistor layer TFTL may include a plurality of transistors TFT (refer to FIG. 5).

The display element layer EML may be disposed on the transistor layer TFTL. The display element layer EML may be disposed in a portion overlapping the display area DDA. The display element layer EML may include at least one of an organic LED (“OLED”) including an organic light-emitting layer, a quantum dot LED including a quantum dot light-emitting layer, an inorganic LED including an inorganic semiconductor, or a micro LED, but is not limited thereto.

The thin film encapsulation layer TFEL may be disposed on the display element layer EML. The thin film encapsulation layer TFEL may be disposed in a portion overlapping the display area DDA and the non-display area NDA. The thin film encapsulation layer TFEL may cover the top surface and the side surface of the display element layer EML and protect the display element layer EML from external oxygen and moisture. The thin film encapsulation layer TFEL may include at least one inorganic film and at least one organic film for encapsulating the display element layer EML. Depending on the embodiment, the thin film encapsulation layer TFEL may be omitted.

The touch sensor layer TSL may be disposed on the thin film encapsulation layer TFEL. The touch sensor layer TSL may be disposed in a portion overlapping the display area DDA and the non-display area NDA. The touch sensor layer TSL may sense the user's touch by a mutual capacitance method or a self-capacitance method. Depending on the embodiment, the touch sensor layer TSL may be omitted.

The color filter layer CFL may be disposed on the touch sensor layer TSL. The color filter layer CFL may be disposed in a portion overlapping the display area DDA and the non-display area NDA. The color filter layer CFL may absorb a part of light coming from the outside of the display device 10 to reduce reflected light due to external light. Accordingly, the color filter layer CFL may prevent color distortion caused by reflection of the external light.

Since the color filter layer CFL is directly disposed on the touch sensor layer TSL, the display device 10 may not desire a separate substrate for the color filter layer CFL. Accordingly, the thickness of the display device 10 may be relatively small. The color filter layer CFL may be omitted depending on the embodiment.

As illustrated in FIG. 2, a portion of the display panel 100 overlapping the sub-region SBA may be bent. When a portion of the display panel 100 is bent, the display driver 200, the circuit board 300, and the touch driver 400 may overlap the main region MA in the third direction DR3.

When a portion of the display panel 100 is bent, a bending protection layer BPL may protect the lower structure disposed to overlap the sub-region SBA from bending stress.

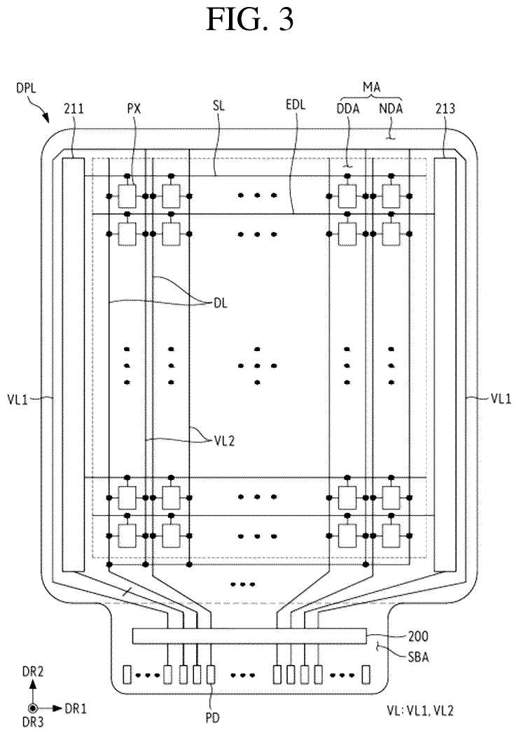

FIG. 3 is a plan view illustrating an embodiment of a display layer of a display device.

Referring to FIG. 3, the display layer DPL may include a plurality of pixels PX in a portion overlapping the display area DDA, a plurality of power lines VL connected to the plurality of pixels PX, a plurality of scan lines SL, a plurality of emission control lines EDL, and a plurality of data lines DL.

Each of the plurality of scan lines SL may extend in the first direction DR1 and may be spaced apart from each other in the second direction DR2 intersecting the first direction DR1. The scan lines SL may be arranged along the second direction DR2. The scan lines SL may sequentially supply a scan signal to the plurality of pixels PX.

The emission control lines EDL may extend in the first direction DR1 and may be spaced apart from each other in the second direction DR2. The emission control lines EDL may be arranged along the second direction DR2. The emission control lines EDL may sequentially supply an emission signal to the plurality of pixels PX.

The data lines DL may extend in the second direction DR2 and may be spaced apart from each other in the first direction DR1. The data lines DL may be arranged along the first direction DR1. The data lines DL may supply data voltages to the plurality of pixels PX. The data voltage may determine the luminance of each of the pixels PX.

The power line VL may include a main power line VL1 and a sub-power line VL2. At least one of a first power voltage (high potential voltage) or a second power voltage (low potential voltage) may be transmitted to the sub-power line VL2 through the main power line VL1 overlapping the non-display area NDA. Hereinafter, the main power line VL1 and the sub-power line VL2 may be collectively referred to as the power line VL.

The non-display area NDA may surround the display area DDA. The non-display area NDA may include a scan driver 211 and an emission control driver 213.

The scan driver 211 may be disposed outside one side of the display area DDA or on one side of the non-display area NDA. The scan driver 211 may include a plurality of driving transistors that generate gate signals based on a gate control signal.

The emission control driver 213 may be disposed outside an opposite side of the display area DDA or on an opposite side of the non-display area NDA. The emission control driver 213 may include a plurality of emission control transistors that generate emission signals based on the emission control signal.

The display layer DPL of an embodiment may include the display driver 200 and a plurality of pad electrodes PD in a portion overlapping the sub-region SBA. The plurality of pad electrodes PD may be spaced apart from each other in the first direction DR1, and the pad electrodes PD may be connected to different wires, respectively.

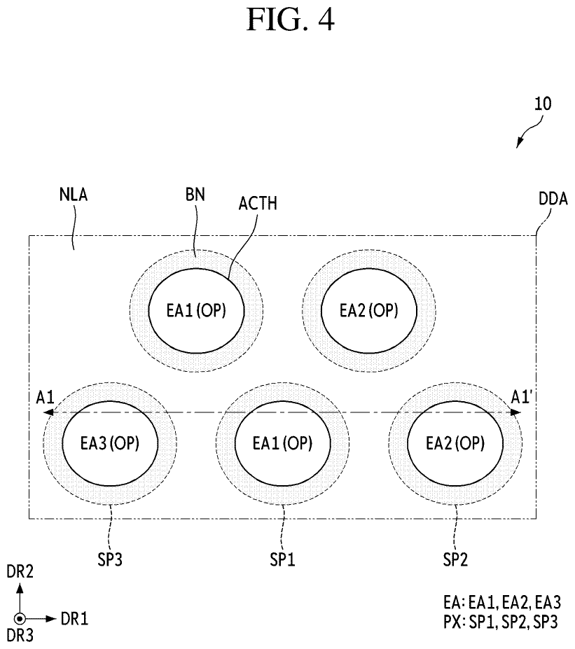

FIG. 4 is a layout diagram illustrating a plurality of pixels arranged in the display area of FIG. 3.

Referring to FIG. 4, the pixel PX of an embodiment may include a first sub-pixel SP1, a second sub-pixel SP2, and a third sub-pixel SP3 disposed in a portion overlapping the display area DDA. The first sub-pixel SP1, the second sub-pixel SP2, and the third sub-pixel SP3 may be spaced apart from each other.

The pixel PX may include an emission area EA. The emission area EA may be a portion where light is emitted. In an embodiment, the first sub-pixel SP1 may include the first emission area EA1, the second sub-pixel SP2 may include the second emission area EA2, and the third sub-pixel SP3 may include the third emission area EA3.

In an embodiment, the first emission area EA1, the second emission area EA2, and the third emission area EA3 may emit light of different colors. In an embodiment, the first emission area EA1 may emit red light, the second emission area EA2 may emit green light, and the third emission area EA3 may emit blue light, for example. However, the disclosure is not limited thereto, and the first emission area EA1, the second emission area EA2, and the third emission area EA3 may emit light of the same color depending on the embodiment.

In an embodiment, the emission area EA may be defined by an opening OP. The opening OP may be defined by an element insulating layer PDL (refer to FIG. 5) to be described later.

In plan view, an anode contact hole ACTH may be defined in a portion overlapping the emission area EA. In other words, in a plan view, the anode contact hole ACTH may be defined in a portion overlapping the opening OP. The anode contact hole ACTH will be described later.

The display device 10 of an embodiment may include a non-emission area NLA in a portion overlapping the display area DDA. The non-emission area NLA may prevent color mixing of light emitted from the first emission area EA1, the second emission area EA2, and the third emission area EA3.

A bank structure BN may be disposed in a portion overlapping the non-emission area NLA. The bank structure BN may be disposed to surround the opening OP or the anode contact hole ACTH. The predetermined planar structure of the bank structure BN will be described later.

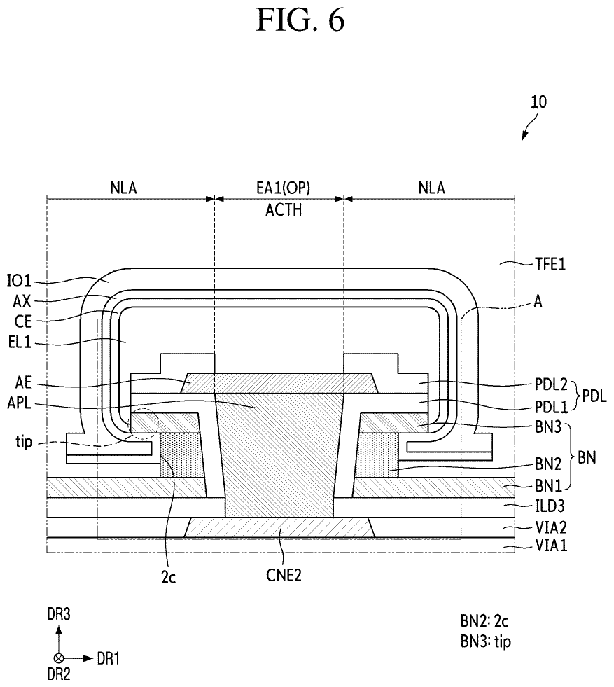

FIG. 5 is a cross-sectional view showing an embodiment of a display layer taken along line A1-A1′ of FIG. 4, and FIG. 6 is an enlarged cross-sectional view of the display element layer overlapping the first emission area in FIG. 5. FIG. 5 illustrates the cross-sectional structure of the first sub-pixel SP1, the second sub-pixel SP2, and the third sub-pixel SP3 in a portion overlapping the display area DDA of the display device 10.

Referring to FIGS. 5 and 6, the transistor layer TFTL may be disposed on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a first via layer VIA1, a second connection electrode CNE2, a second via layer VIA2, and a third insulating layer ILD3.

The first buffer layer BF1 may be disposed on the substrate SUB. The first buffer layer BF1 may include an inorganic film capable of preventing penetration of air or moisture. In an embodiment, the first buffer layer BF1 may include a plurality of inorganic films alternately stacked, for example.

The lower metal layer BML may be disposed on the first buffer layer BF1. The lower metal layer BML may include a conductive metal, and may be formed as a single layer or multiple layers including any one of molybdenum (Mo), aluminum (Al), chromium (Cr), gold (Au), titanium (Ti), nickel (Ni), neodymium (Nd) and copper (Cu) or any alloys thereof, for example.

The second buffer layer BF2 may cover the first buffer layer BF1 and the lower metal layer BML. The second buffer layer BF2 may include an inorganic film capable of preventing penetration of air or moisture. In an embodiment, the second buffer layer BF2 may include a plurality of inorganic films alternately stacked, for example.

The transistor TFT may be disposed on the second buffer layer BF2, and the transistor TFT may constitute a pixel circuit. In an embodiment, the transistor TFT may be a switching transistor or a driving transistor of the pixel circuit, for example.

The transistor TFT may include an active layer ACT, a source electrode SE, a drain electrode DE, and a gate electrode GE.

The active layer ACT may be disposed on the second buffer layer BF2. The active layer ACT may overlap the gate electrode GE in the third direction DR3, and may be insulated from the gate electrode GE by the gate insulating layer GI. The source electrode SE and drain electrode DE may be portions of the active layer ACT that have become conductive.

The gate insulating layer GI may be disposed on the active layer ACT. The gate insulating layer GI may cover the active layer ACT and the second buffer layer BF2 to insulate the gate electrode GE from the active layer ACT. The gate insulating layer GI may define a contact hole through which the first connection electrode CNE1 passes.

The gate electrode GE may be disposed on the gate insulating layer GI. The gate electrode GE may overlap the active layer ACT while the gate insulating layer GI is interposed between the gate electrode GE and the gate insulating layer GI.

The gate electrode GE may include a conductive metal, and may be formed as a single layer or multiple layers including any one of molybdenum (Mo), aluminum (Al), chromium (Cr), gold (Au), titanium (Ti), nickel (Ni), neodymium (Nd) and copper (Cu) or any alloys thereof, for example.

The first insulating layer ILD1 may cover the gate electrode GE and the gate insulating layer GI. The first insulating layer ILD1 may define a contact hole through which the first connection electrode CNE1 passes. The contact hole of the first insulating layer ILD1 may be extended to the contact hole of the gate insulating layer GI and the contact hole of the second insulating layer ILD2.

The capacitor electrode CPE may be disposed on the first insulating layer ILD1. The capacitor electrode CPE may overlap the gate electrode GE in the third direction DR3. The capacitor electrode CPE and the gate electrode GE may form a capacitance.

The second insulating layer ILD2 may cover the capacitor electrode CPE and the first insulating layer ILD1. The second insulating layer ILD2 may define a contact hole through which the first connection electrode CNE1 passes. The contact hole of the second insulating layer ILD2 may be extended to the contact hole of the first insulating layer ILD1 and the contact hole of the gate insulating layer GI.

The first connection electrode CNE1 may be disposed on the second insulating layer ILD2. The first connection electrode CNE1 may electrically connect the drain electrode DE of the transistor TFT to the second connection electrode CNE2. The first connection electrode CNE1 may be inserted into a contact hole provided in the first insulating layer ILD1, the second insulating layer ILD2, and the gate insulating layer GI to contact the drain electrode DE of the transistor TFT.

The first via layer VIA1 may be disposed on the first connection electrode CNE1 and the second insulating layer ILD2. The first via layer VIA1 may flatten the lower structure. The first via layer VIA1 may include a contact hole through which the second connection electrode CNE2 passes.

The first via layer VIA1 may include an organic insulating material. In an embodiment, the first via layer VIA1 may include acrylic resin, polyimide, polyamide, benzocyclobutene, phenol resin, or the like, for example.

The second connection electrode CNE2 may be disposed on the first via layer VIA1. The second connection electrode CNE2 may be disposed in a portion overlapping the emission area EA. The second connection electrode CNE2 may be inserted into a contact hole defined in the first via layer VIA1 to contact the first connection electrode CNE1.

The second via layer VIA2 may be disposed on the first via layer VIA1. The second via layer VIA2 may flatten the stepped portion formed by the second connection electrode CNE2.

The second via layer VIA2 may include an organic material. In an embodiment, the second via layer VIA2 may include acrylic resin, silicone resin, silicone acrylic resin, epoxy resin, polyimide, polyamide, benzocyclobutene, phenol resin, or the like, for example.

The third insulating layer ILD3 may be disposed on the second via layer VIA2. The third insulating layer ILD3 may assist in preventing an outgas caused by an organic material of the second via layer VIA2 from permeating into the display element layer EML.

The third insulating layer ILD3 may include an inorganic insulating material. In an embodiment, the third insulating layer ILD3 may include or consist of at least one of silicon nitride, silicon oxide, or silicon oxynitride, for example.

The display element layer EML may be disposed on the transistor layer TFTL. The display element layer EML may include the bank structure BN, the element insulating layer PDL, a light-emitting element ED, an anode planarization layer APL, and an element inorganic layer IO.

The bank structure BN may be disposed on the third insulating layer ILD3. The bank structure BN may be disposed in a portion overlapping the emission area EA or/and the opening OP or/and the anode contact hole ACTH.

The bank structure BN may assist first to third light-emitting elements ED1, ED2, and ED3 to be disposed in a portion overlapping the first to third emission areas EA1, EA2, and EA3, respectively. In addition, the bank structure BN may assist cathode electrodes CE spaced apart from each other in the first to third emission areas EA1, EA2, and EA3 to be electrically connected.

The bank structure BN may include a first bank layer BN1, a second bank layer BN2, and a third bank layer BN3. The first bank layer BN1, the second bank layer BN2, and the third bank layer BN3 may be sequentially stacked in the third direction DR3.

The first bank layer BN1 may be disposed on the third insulating layer ILD3. The first bank layer BN1 may cover the third insulating layer ILD3 in a portion overlapping the emission area EA and the non-emission area NLA.

The first bank layer BN1 may assist in applying a relatively low potential voltage to the cathode electrode CE. The first bank layer BN1 may include a conductive metal having etching resistance. In an embodiment, the first bank layer BN1 may include or consist of titanium (Ti).

The first bank layer BN1 may be penetrated by the anode contact hole ACTH in a portion overlapping the emission area EA. In other words, the first bank layer BN1 may be disposed to surround the anode contact hole ACTH, and may be formed in the form of one conductive pattern disposed to surround the anode contact hole ACTH.

The second bank layer BN2 may be disposed in contact with and on the first bank layer BN1. The second bank layer BN2 may be penetrated by the anode contact hole ACTH in a portion overlapping the emission area EA. In other words, the second bank layer BN2 may be disposed to surround the anode contact hole ACTH.

A plurality of second bank layers BN2 may be formed, and the plurality of second bank layers BN2 may be spaced apart from each other in the first direction DR1. In other words, the plurality of second bank layers BN2 may be disposed in portions overlapping the first to third emission areas EA1, EA2, and EA3, respectively, and the respective second bank layers BN2 may be spaced apart from each other in an island shape.

The second bank layer BN2 may assist in electrically connecting the first bank layer BN1 to the third bank layer BN3. In other words, the second bank layer BN2 may be electrically connected to the first bank layer BN1 and the third bank layer BN3. Accordingly, the second bank layer BN2 disposed in a portion overlapping the first emission area EA1, the second bank layer BN2 disposed in a portion overlapping the second emission area EA2, and the second bank layer BN2 disposed in a portion overlapping the third emission area EA3 may be electrically connected by the first bank layer BN1.

The second bank layer BN2 may include a metal with relatively high electrical conductivity. In an embodiment, the second bank layer BN2 may include aluminum (Al).

The third bank layer BN3 may be disposed in contact with and on the second bank layer BN2. The third bank layer BN3 may be penetrated by the anode contact hole ACTH in a portion overlapping the emission area EA. In other words, the third bank layer BN3 may be disposed to surround the anode contact hole ACTH.

A plurality of third bank layers BN3 may be formed, and the plurality of third bank layers BN3 may be spaced apart from each other in the first direction DR1. In other words, the plurality of third bank layers BN3 may be disposed in portions overlapping the first to third emission areas EA1, EA2, and EA3, respectively, and the respective third bank layers BN3 may be spaced apart from each other in an island shape.

The third bank layer BN3 may include a conductive metal having etching resistance. In an embodiment, the third bank layer BN3 may be titanium (Ti).

In an embodiment, the third bank layer BN3 disposed in a portion overlapping the first emission area EA1, the third bank layer BN3 disposed in a portion overlapping the second emission area EA2, and the third bank layer BN3 disposed in a portion overlapping the third emission area EA3 may be electrically connected by the second bank layer BN2 and the first bank layer BN1. Redundant descriptions are omitted.

As illustrated in FIG. 6, the second bank layer BN2 may include a first side surface 2c facing the non-emission area NLA, and the third bank layer BN3 may include a tip protruding more in the first direction DR1 than the first side surface 2c of the second bank layer BN2. Accordingly, the first side surface 2c of the second bank layer BN2 and the tip of the third bank layer BN3 may form an undercut, and the bank structure BN may have an overhang structure.

In the display device 10 of an embodiment, the bank structure BN includes the tip, so that the first light-emitting element ED1, the second light-emitting element ED2, and the third light-emitting element ED3 spaced apart from each other may be formed without a separate fine metal mask in the fabrication process. The fabrication process will be described later.

The element insulating layer PDL may include a first element insulating layer PDL1 and a second element insulating layer PDL2.

The first element insulating layer PDL1 may be disposed on the third bank layer BN3. The first element insulating layer PDL1 may cover the third bank layer BN3, and may be disposed to overlap the tip of the third bank layer BN3 in the third direction DR3.

The first element insulating layer PDL1 may be penetrated by the anode contact hole ACTH in a portion overlapping the emission area EA. In other words, the first element insulating layer PDL1 may be disposed to surround the anode contact hole ACTH.

The first element insulating layer PDL1 may separate and insulate the bank structure BN and an anode electrode AE from each other to prevent the contact between the bank structure BN and the anode electrode AE. Accordingly, the first element insulating layer PDL1 may cover an entirety of the side surface of the bank structure BN that faces the anode contact hole ACTH. Accordingly, the first element insulating layer PDL1 may solve short-circuit defects of the display device 10 due to the contact between the anode electrode AE and the bank structure BN.

The first element insulating layer PDL1 may include or consist of an inorganic insulating material. In an embodiment, the first element insulating layer PDL1 may include or consist of at least one of silicon nitride, silicon oxide, or silicon oxynitride, for example.

The second element insulating layer PDL2 may be disposed on the first element insulating layer PDL1. The second element insulating layer PDL2 may define the opening OP and may expose the anode electrode AE in a portion overlapping the opening OP. In other words, the second element insulating layer PDL2 may be disposed to surround the opening OP, and may cover the edge of the anode electrode AE.

The second element insulating layer PDL2 may include an inorganic insulating material. In an embodiment, the second element insulating layer PDL2 may include or consist of at least one of silicon nitride, silicon oxide, or silicon oxynitride, for example.

Although it is illustrated in the drawing that the width of the anode contact hole ACTH and the width of the opening OP are the same in the first direction DR1, the disclosure is not limited thereto. The anode contact hole ACTH and the opening OP may be defined to overlap in the third direction DR3, but the width of the anode contact hole ACTH and the width of the opening OP may be different from each other.

The light-emitting element ED may be disposed on the bank structure BN. The light-emitting element ED may overlap the bank structure BN and the element insulating layer PDL in the third direction DR3. In addition, the light-emitting element ED may overlap the anode contact hole ACTH in the third direction DR3.

The display device 10 of an embodiment may be applied to a high-resolution electronic device. Therefore, the plurality of light-emitting elements ED included in the display device 10 may be desired to be arranged while securing an appropriate separation distance in a narrow area. Accordingly, the display device 10 of an embodiment may include the plurality of light-emitting elements that are efficiently arranged in a narrow area by forming the light-emitting elements ED to be disposed on the bank structure BN.

The light-emitting element ED may include a first light-emitting element ED1 disposed in the first emission area EA1, a second light-emitting element ED2 disposed in the second emission area EA2, and a third light-emitting element ED3 disposed in the third emission area EA3. The first light-emitting element ED1, the second light-emitting element ED2, and the third light-emitting element ED3 may be spaced apart from each other.

In an embodiment, the first light-emitting element ED1 may include the anode electrode AE, the first light-emitting layer EL1, the cathode electrode CE, and an auxiliary electrode AX, the second light-emitting element ED2 may include the anode electrode AE, the second light-emitting layer EL2, the cathode electrode CE, and the auxiliary electrode AX, and the third light-emitting element ED3 may include the anode electrode AE, the third light-emitting layer EL3, the cathode electrode CE, and the auxiliary electrode AX.

The first light-emitting element ED1, the second light-emitting element ED2, and the third light-emitting element ED3 may emit light of different colors. In an embodiment, the first light-emitting element ED1 may emit red light, the second light-emitting element ED2 may emit green light, and the third light-emitting element ED3 may emit blue light, for example. The colors emitted by the first light-emitting element ED1, the second light-emitting element ED2, and the third light-emitting element ED3 may be determined by the first light-emitting layer EL1, the second light-emitting layer EL2, and the third light-emitting layer EL3.

In an embodiment, the anode contact hole ACTH may be defined in a portion overlapping the emission area EA. The anode contact hole ACTH may be defined while penetrating the third insulating layer ILD3, the first bank layer BN1, the second bank layer BN2, and the third bank layer BN3.

In the display device 10 of an embodiment, a separate area for the anode contact hole ACTH is formed to overlap the emission area EA without being formed in a separate space, so that the contact area of the anode electrode AE and the emission area EA may be integrated. Therefore, in the display device 10 of an embodiment, the plurality of emission areas EA may be efficiently disposed in a narrow area.

The anode planarization layer APL may be disposed on the second connection electrode CNE2 in a portion overlapping the anode contact hole ACTH. The anode planarization layer APL may be disposed in a portion overlapping the emission area EA or the opening OP, and may not overlap the non-emission area NLA. The anode planarization layer APL may contact the second connection electrode CNE2, and may be electrically connected to the second connection electrode CNE2. In addition, the anode planarization layer APL may contact the third insulating layer ILD3 and the first element insulating layer PDL1 in a portion overlapping the anode contact hole ACTH.

The anode planarization layer APL may flatten the stepped portion formed in a portion overlapping the anode contact hole ACTH. In other words, the anode planarization layer APL may fill the stepped portion formed in a portion overlapping the anode contact hole ACTH.

The anode planarization layer APL may include a conductive metal and/or a transparent conductive oxide (“TCO”) material. In an embodiment, the anode planarization layer APL may include any one of molybdenum (Mo), aluminum (Al), chromium (Cr), gold (Au), titanium (Ti), nickel (Ni), neodymium (Nd) and copper (Cu), or at least one of indium-zinc-oxide (“IZO”) or indium-tin-oxide (“ITO”), for example.

The anode electrode AE may be disposed on the first element insulating layer PDL1 and the anode planarization layer APL. The anode electrode AE may contact the anode planarization layer APL and the first element insulating layer PDL1.

The anode planarization layer APL and the anode electrode AE may be electrically connected. Accordingly, the anode electrode AE may be electrically connected to the second connection electrode CNE2 by the anode planarization layer APL.

The anode electrode AE may be disposed in a portion overlapping the emission area EA or/and the opening OP or/and the anode contact hole ACTH. The anode electrode AE may be exposed in a portion overlapping the opening OP, and the anode electrode AE may contact the first to third light-emitting layers EL1, EL2, and EL3 in a portion overlapping the opening OP. The edge of the anode electrode AE that does not overlap the opening OP may be covered by the second element insulating layer PDL2.

The anode electrode AE may have a stacked structure formed by stacking a material layer having a relatively high work function, such as indium tin oxide (“ITO”), indium zinc oxide (“IZO”), zinc oxide (ZnO) and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or any combinations thereof. In an embodiment, the anode electrode AE may have a multilayer structure of ITO/Mg, ITO/MgF, ITO/Ag, and ITO/Ag/ITO, for example, but are not limited thereto.

In the fabrication process of the display device 10, the anode planarization layer APL and the anode electrode AE may be formed by different processes. Specifically, the anode planarization layer APL may be formed by a deposition process, a chemical mechanical polishing (“CMP”) process, and a patterning process, and the anode electrode AE may be formed by a deposition and patterning process. Accordingly, a boundary surface may be formed on one surface where the anode planarization layer APL and the anode electrode AE face each other.

Therefore, in the display device 10 of an embodiment, due to the boundary surface on one surface where the anode planarization layer APL and the anode electrode AE face each other, it may be seen that the anode planarization layer APL and the anode electrode AE are formed in different processes. The fabrication process will be described later.

The first to third light-emitting layers EL1, EL2, and EL3 may be disposed on the anode electrode AE. The first to third light-emitting layers EL1, EL2, and EL3 may be disposed in a portion overlapping the emission area EA and the non-emission area NLA. The first to third light-emitting layers EL1, EL2, and EL3 may overlap the bank structure BN and the element insulating layer PDL in the third direction DR3.

The first to third light-emitting layers EL1, EL2, and EL3 may contact the anode electrode AE in a portion overlapping the opening OP, and may cover an entirety of the second element insulating layer PDL2 in a portion overlapping the non-emission area NLA.

In an embodiment, when the display device does not include the anode planarization layer APL, the anode electrode AE may cover the stepped portion formed in a portion overlapping the anode contact hole ACTH, for example. This may mean that the first to third light-emitting layers EL1, EL2, and EL3 formed on the anode electrode AE also cover the stepped portion formed in a portion overlapping the anode contact hole ACTH.

In an embodiment, when the first to third light-emitting layers EL1, EL2, and EL3 cover the stepped portion formed in a portion overlapping the anode contact hole ACTH, the first to third light-emitting layers EL1, EL2, and EL3 may be formed to have a thickness less than a predetermined range in a portion overlapping the edge of the anode contact hole ACTH, which may cause reliability defects (e.g., light-emitting layer shadow defects) of the display device 10, for example.

The above-described reliability defects (e.g., light-emitting layer shadow defects) may be defects in which the luminance of the display device 10 is measured to be partially less than a predetermined range because the thickness of the material forming the first to third light-emitting layers EL1, EL2, and EL3 is partially less than a predetermined range.

Therefore, the display device 10 of an embodiment includes the anode planarization layer APL in a portion overlapping the anode contact hole ACTH, so that the stepped portion formed in a portion overlapping the anode contact hole ACTH may be flattened. Accordingly, the anode electrode AE may have a relatively flat shape in a portion overlapping the anode contact hole ACTH.

Further, since the display device 10 of an embodiment includes the anode planarization layer APL in a portion overlapping the anode contact hole ACTH, the first to third light-emitting layers EL1, EL2, and EL3 may be formed with a uniform thickness in a portion overlapping the anode contact hole ACTH. Accordingly, the display device 10 may solve reliability defects (e.g., light-emitting layer shadow defects).

The first to third light-emitting layers EL1, EL2, and EL3 may be an organic light-emitting layer including an organic material. The first to third light-emitting layers EL1, EL2, and EL3 may include all materials that are commonly used.

The first light-emitting layer EL1, the second light-emitting layer EL2, and the third light-emitting layer EL3 may emit light of different colors. In an embodiment, the first light-emitting layer EL1 may emit red light, the second light-emitting layer EL2 may emit green light, and the third light-emitting layer EL3 may emit blue light, for example, but the disclosure is not limited thereto.

The first light-emitting layer EL1 may be disposed in a portion overlapping the first emission area EA1, the second light-emitting layer EL2 may be disposed in a portion overlapping the second emission area EA2, and the third light-emitting layer EL3 may be disposed in a portion overlapping the third emission area EA3. The first light-emitting layer EL1, the second light-emitting layer EL2, and the third light-emitting layer EL3 may be spaced apart from each other in a portion overlapping the non-emission area NLA.

In the display device 10 of an embodiment, the third bank layer BN3 includes the tip, so that the first light-emitting layer EL1, the second light-emitting layer EL2, and the third light-emitting layer EL3 spaced apart from each other may be formed without using a separate fine metal mask in the fabrication process of the display device 10. The fabrication process will be described later.

The cathode electrodes CE may be disposed on the first to third light-emitting layers EL1, EL2, and EL3. The cathode electrode CE may be disposed in a portion overlapping the emission area EA and the non-emission area NLA. The cathode electrode CE may cover an entirety of the first to third light-emitting layers EL1, EL2, and EL3.

The cathode electrode CE may contact the bank structure BN, and thus may be electrically connected to the bank structure BN. Specifically, the cathode electrode CE may contact the tip of the third bank layer BN3.

The cathode electrode CE may include a transparent conductive material, so that light generated in the first to third light-emitting layers EL1, EL2, and EL3 may be emitted. In an embodiment, the cathode electrode CE may include a material layer having a relatively low work function, such as Li, Ca, LiF/Ca, LiF/Al, Al, Mg, Ag, Pt, Pd, Ni, Au Nd, Ir, Cr, BaF, Ba or a compound or combination thereof (e.g., a combination of Ag and Mg), for example. The cathode electrode CE may further include a transparent metal oxide layer disposed on the material layer having a relatively low work function.

In an embodiment, the cathode electrode CE disposed in a portion overlapping the first emission area EA1, the cathode electrode CE disposed in a portion overlapping the second emission area EA2, and the cathode electrode CE disposed in a portion overlapping the third emission area EA3 may be spaced apart from each other. The cathode electrodes CE spaced apart from each other in the first to third emission areas EA1, EA2, and EA3 may be electrically connected by the bank structure BN. Specifically, the cathode electrodes CE spaced apart from each other in the first to third emission areas EA1, EA2, and EA3 may contact the third bank layer BN3 spaced apart from each other in the first to third emission areas EA1, EA2, and EA3, and may be electrically connected to each other by the second bank layer BN2 and the first bank layer BN1 that are electrically connected to the third bank layer BN3.

In the display device 10 of an embodiment, the third bank layer BN3 includes the tip, so that the cathode electrodes CE spaced apart from each other in the first to third emission areas EA1, EA2, and EA3 may be formed without a separate fine metal mask. The fabrication process will be described later.

The auxiliary electrode AX may be disposed on the cathode electrode CE. The auxiliary electrode AX may be disposed in a portion overlapping the emission area EA and the non-emission area NLA. The auxiliary electrode AX may cover an entirety of the cathode electrode CE. The auxiliary electrode AX may assist in electrically connecting the cathode electrode CE.

The auxiliary electrode AX may include a transparent conductive oxide (“TCO”) material. In an embodiment, the auxiliary electrode AX may include at least one of indium-zinc-oxide (“IZO”) or indium-tin-oxide (“ITO”), for example.

In an embodiment, the auxiliary electrode AX disposed in a portion overlapping the first emission area EA1, the auxiliary electrode AX disposed in a portion overlapping the second emission area EA2, and the auxiliary electrode AX disposed in a portion overlapping the third emission area EA3 may be spaced apart from each other. The auxiliary electrodes AX spaced apart from each other in the first to third emission areas EA1, EA2, and EA3 may be electrically connected by the bank structure BN. Specifically, the auxiliary electrodes AX spaced apart from each other in the first to third emission areas EA1, EA2, and EA3 may contact the third bank layer BN3 spaced apart from each other in the first to third emission areas EA1, EA2, and EA3, and may be electrically connected to each other by the second bank layer BN2 and the first bank layer BN1 that are electrically connected to the third bank layer BN3.

In an embodiment, the auxiliary electrode AX may be spaced apart from the first bank layer BN1 in the third direction DR3 in a portion overlapping the non-emission area NLA. An organic encapsulation layer TFE1 to be described later may be disposed in a spaced portion between the auxiliary electrode AX and the first bank layer BN1.

The element inorganic layer IO may be disposed on the light-emitting element ED. The element inorganic layer IO may completely cover the light-emitting element ED, thereby reducing or preventing oxygen or moisture from penetrating into the light-emitting element ED.

The element inorganic layer IO may include or consist of an inorganic insulating material. In an embodiment, the element inorganic layer IO may include or consist of any one of silicon nitride, silicon oxide, and silicon oxynitride, for example.

The element inorganic layer IO may include a first element inorganic layer IO1, a second element inorganic layer IO2, and a third element inorganic layer IO3. The first element inorganic layer IO1 may be disposed on the first light-emitting element ED1 in the first emission area EA1, the second element inorganic layer IO2 may be disposed on the second light-emitting element ED2 in the second emission area EA2, and the third element inorganic layer IO3 may be disposed on the third light-emitting element ED3 in the third emission area EA3. The first element inorganic layer IO1, the second element inorganic layer IO2, and the third element inorganic layer IO3 may be spaced apart from each other in a portion overlapping the non-emission area NLA.

In the drawing, the first element inorganic layer IO1, the second element inorganic layer IO2, and the third element inorganic layer IO3 appear to be formed in the same layer, but in the fabrication process of the display device 10, the first element inorganic layer IO1 may be formed after the first light-emitting element ED1 is formed, the second element inorganic layer IO2 may be formed after the second light-emitting element ED2 is formed, and the third element inorganic layer IO3 may be formed after the third light-emitting element ED3 is formed. The fabrication process will be described later.

The thin film encapsulation layer TFEL may be disposed on the display element layer EML. The thin film encapsulation layer TFEL may include the organic encapsulation layer TFE1 and an inorganic encapsulation layer TFE3.

The organic encapsulation layer TFE1 of an embodiment may be disposed on the element inorganic layer IO. In an embodiment, the organic encapsulation layer TFE1 may be entirely in contact with and cover the first element inorganic layer IO1, the second element inorganic layer IO2, and the third element inorganic layer IO3, for example.

The organic encapsulation layer TFE1 may flatten a stepped portion formed according to the profile of the lower structure. The organic encapsulation layer TFE1 may fill the spaced portion between the auxiliary electrode AX and the first bank layer BN1 in a portion overlapping the non-emission area NLA.

The organic encapsulation layer TFE1 may include a polymer-based material. In an embodiment, the organic encapsulation layer TFE1 may include acrylic resin, silicone resin, epoxy resin, silicone acrylic resin, polyimide, polyethylene, or the like, for example.

The inorganic encapsulation layer TFE3 may be disposed on the organic encapsulation layer TFE1. The inorganic encapsulation layer TFE3 may protect the lower structure from permeation of moisture and oxygen. Depending on the embodiment, the inorganic encapsulation layer TFE3 may be omitted.

The inorganic encapsulation layer TFE3 may include or consist of an inorganic insulating material. In an embodiment, the inorganic encapsulation layer TFE3 may include or consist of any one of silicon nitride, silicon oxide, and silicon oxynitride, for example.

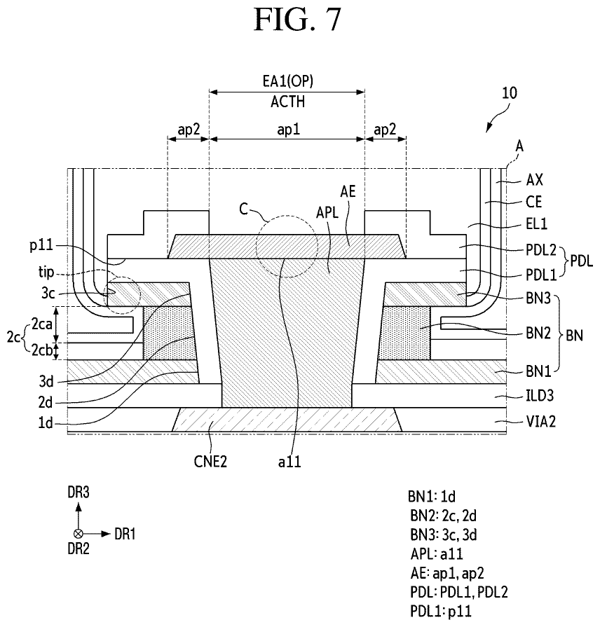

FIG. 7 is an enlarged cross-sectional view of area A of FIG. 6.

Referring to FIG. 7 in addition to FIGS. 1 to 6, the bank structure BN may have an asymmetrical structure in a portion facing the anode contact hole ACTH and a portion opposing the anode contact hole ACTH.

In an embodiment, in a portion facing the anode contact hole ACTH, a second side surface 1d of the first bank layer BN1, a second side surface 2d of the second bank layer BN2, and a second side surface 3d of the third bank layer BN3 may be disposed on the same line. Being disposed on the same line described above may have the same meaning as being aligned or being extended to be disposed.

The second side surface 1d of the first bank layer BN1, the second side surface 2d of the second bank layer BN2, and the second side surface 3d of the third bank layer BN3 are removed by the same etching process in the fabrication process of the display device 10, and thus may be disposed on the same line. The fabrication process will be described later.

In an embodiment, in the portion opposing the portion facing the anode contact hole ACTH, a first side surface 3c of the third bank layer BN3 may protrude more in the first direction DR1 than the first side surface 2c of the second bank layer BN2. That is, the third bank layer BN3 may include the tip protruding more in the first direction DR1 than the first side surface 2c of the second bank layer BN2. Redundant descriptions are omitted.

In an embodiment, the cathode electrode CE may be disposed in contact with and on the first side surface 3c of the third bank layer BN3. In addition, the auxiliary electrode AX may contact the tip of the third bank layer BN3 and, further, the auxiliary electrode AX may contact the second bank layer BN2.

In an embodiment, the first side surface 2c of the second bank layer BN2 may include a first portion 2ca and a second portion 2cb depending on the contact portion. The first portion 2ca may be a portion in contact with the auxiliary electrode AX, and the second portion 2cb may be a portion in contact with the organic encapsulation layer TFE1.

The area where the auxiliary electrode AX of an embodiment contacts the bank structure BN may be greater than the area where the cathode electrode CE contacts the bank structure BN.

In an embodiment, the first bank layer BN1, the second bank layer BN2, and the third bank layer BN3 may be spaced apart from the anode planarization layer APL while the first element insulating layer PDL1 is interposed between the first to third bank layers BN1 to BN3 and the anode planarization layer APL. The first bank layer BN1, the second bank layer BN2, and the third bank layer BN3 may be disposed to surround the anode planarization layer APL. The first element insulating layer PDL1 may be entirely in contact with and cover the second side surface 1d of the first bank layer BN1, the second side surface 2d of the second bank layer BN2, and the second side surface 3d of the third bank layer BN3.

The second element insulating layer PDL2 may cover the edge of the anode electrode AE, and further may contact the first element insulating layer PDL1.

The anode electrode AE may include a first portion ap1 and a second portion ap2 depending on the overlapping portion. The first portion ap1 may be a portion that contacts or overlaps the anode planarization layer APL, and the second portion ap2 may be a portion that contacts or overlaps the first element insulating layer PDL1. The first portion ap1 may be the center portion of the anode electrode AE, and the second portion ap2 may be the edge portion of the anode electrode AE.

In an embodiment, the anode planarization layer APL may include a first surface a11 facing the anode electrode AE. The first surface a11 of the anode planarization layer APL may extend in the first direction DR1 to be disposed on the same line with the first surface p11 of the first element insulating layer PDL1. The first surface p11 of the first element insulating layer PDL1 may be a surface facing the anode electrode AE. The first surface a11 of the anode planarization layer APL may have a polished surface. A detailed description thereof will be described later.

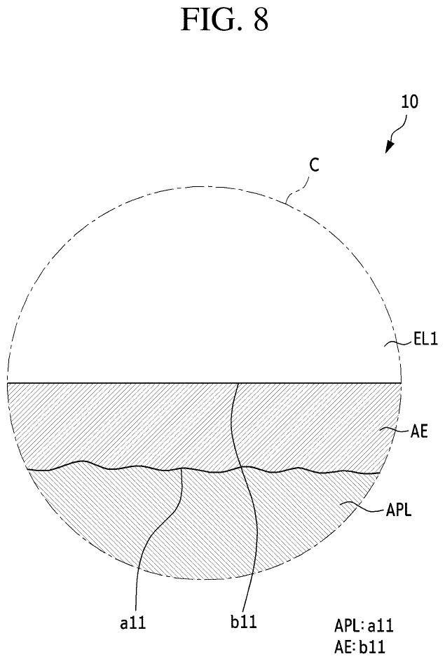

FIG. 8 is an enlarged plan view of area ‘C’ of FIG. 7.

Referring to FIG. 8 in addition to FIGS. 1 to 7, the anode planarization layer APL of an embodiment may be formed by performing a CMP process in the fabrication process. This may mean that a part of the anode planarization layer APL is physically or chemically polished by the CMP process. Therefore, the first surface a11 of the anode planarization layer APL may include physically or chemically polished surface characteristics.

In an embodiment, the first surface a11 of the anode planarization layer APL may have rougher or more curved surface characteristics than those of the first surface b11 of the anode electrode AE formed by the deposition process, for example. The shape of the first surface a11 of the anode planarization layer APL and the first surface b11 of the anode electrode AE may be checked using a cross-section analysis device such as a focused ion beam or a scanning electron microscope.

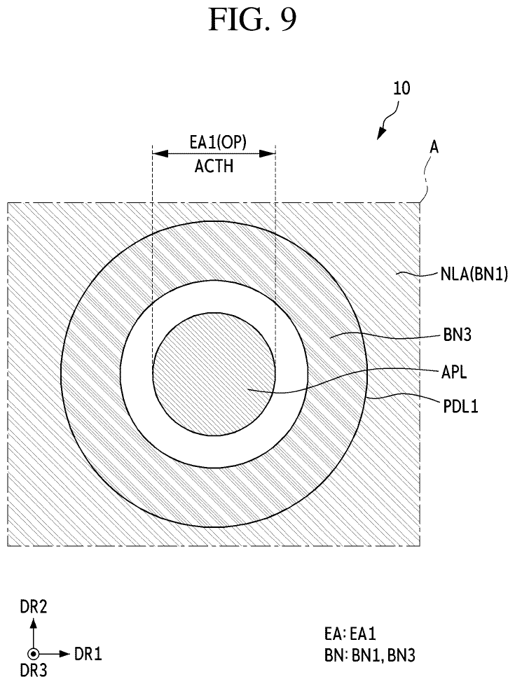

FIG. 9 is a plan view illustrating the arrangement of the bank structure, the anode planarization layer, and the first element insulating layer in FIG. 7.

Referring to FIG. 9 in addition to FIGS. 1 to 8, the anode planarization layer APL may be disposed in a portion overlapping the emission area EA and/or the opening OP and/or the anode contact hole ACTH in a plan view. The anode planarization layer APL may not overlap the non-emission area NLA in a plan view.

The first element insulating layer PDL1 may expose the anode planarization layer APL in a plan view, and the first element insulating layer PDL1 may be disposed to surround the anode planarization layer APL in a plan view. The first element insulating layer PDL1 may cover an entirety of the third bank layer BN3 of the bank structure BN in a plan view.

The bank structure BN may be spaced apart from the anode planarization layer APL while the first element insulating layer PDL1 is interposed between the bank structure BN and the anode planarization layer APL in a plan view. The bank structure BN may be disposed to surround the anode planarization layer APL in a plan view.

Specifically, in a plan view, the third bank layer BN3 of the bank structure BN may be disposed to surround the anode planarization layer APL, and may be formed in an island-shaped conductive pattern. Further, in a plan view, the first bank layer BN1 of the bank structure BN may be disposed to surround the anode planarization layer APL, and may be entirely formed in a portion overlapping the non-emission area NLA. In plan view, a part of the first bank layer BN1 may be covered by the third bank layer BN3.

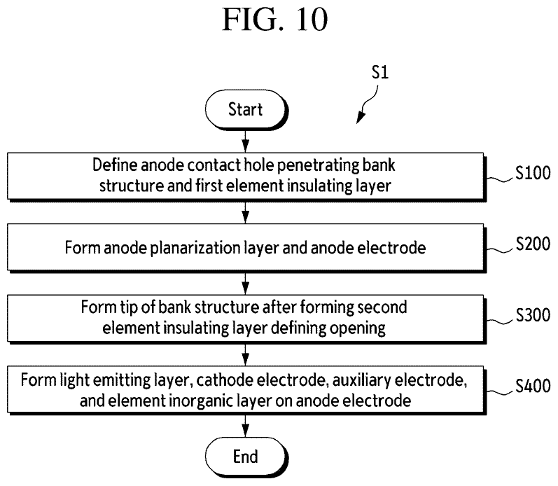

FIG. 10 is a flowchart illustrating a method for fabricating the display element layer of FIG. 5.

Referring to FIG. 10, a method S1 for fabricating the display element layer EML included in the display device 10 in an embodiment may include defining an anode contact hole penetrating a bank structure and a first element insulating layer (operation S100), forming an anode planarization layer and an anode electrode (operation S200), forming a tip of the bank structure after a second element insulating layer that defines an opening is defined (operation S300), and forming a light-emitting layer, a cathode electrode, an auxiliary electrode, and an element inorganic layer on the anode electrode (operation S400).

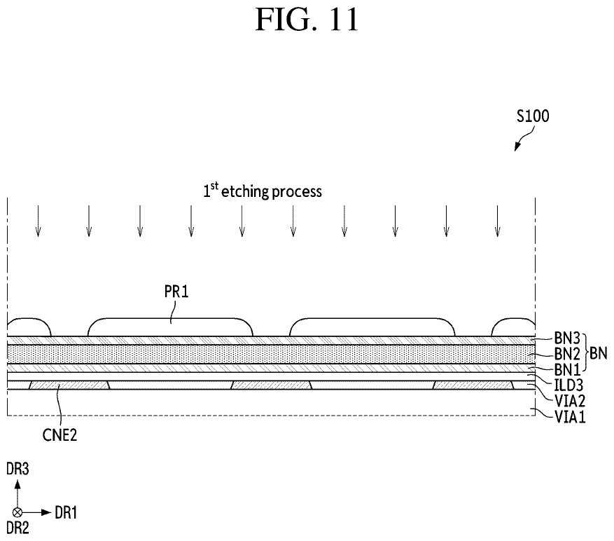

FIGS. 11 to 13 are cross-sectional views showing operation S100 of FIG. 10.

Referring to FIGS. 11 to 13, the operation S100 of defining an anode contact hole penetrating a bank structure and a first element insulating layer will be described.

First, a plurality of second connection electrodes CNE2 are formed on the first via layer VIA1, and the second via layer VIA2, the third insulating layer ILD3, and the bank structure BN are entirely formed. The bank structure BN may include a first bank layer BN1, a second bank layer BN2, and a third bank layer BN3 stacked in that order.

In the process, the second bank layer BN2 and the third bank layer BN3 may include different materials from each other. In an embodiment, the third bank layer BN3 may include a material having an etching resistance higher than that of the second bank layer BN2, for example. Redundant descriptions are omitted.

Although not shown in the drawing, the thin film transistor layer TFTL including the first via layer VIA1 and the second via layer VIA2 may be disposed on the substrate SUB, and the predetermined structure of the thin film transistor layer TFTL is the same as that shown in FIG. 5.

Next, a photoresist PR1 is formed on the third bank layer BN3, and a first etching process (1^{st} etching process) is performed. In the process, a plurality of photoresists PR1 may be formed, and may be disposed in a portion that does not overlap the second connection electrode CNE2.

In the process, the first etching process may be performed as a dry etching process. In an embodiment, the dry etching process may be formed by a reactive ion etching (“RIE”) process using a reaction gas such as CHF₃, CH₃F, CH₂F₂, CHF₆, CF₄, C₂F₆, C₃F₆, or the like and a sputtering gas such as Ar, O₂/Ar, or the like. In this case, an inductively coupled plasma (“ICP”) source or a capacitively coupled plasma (“CCP”) source may be used as a plasma source, for example.

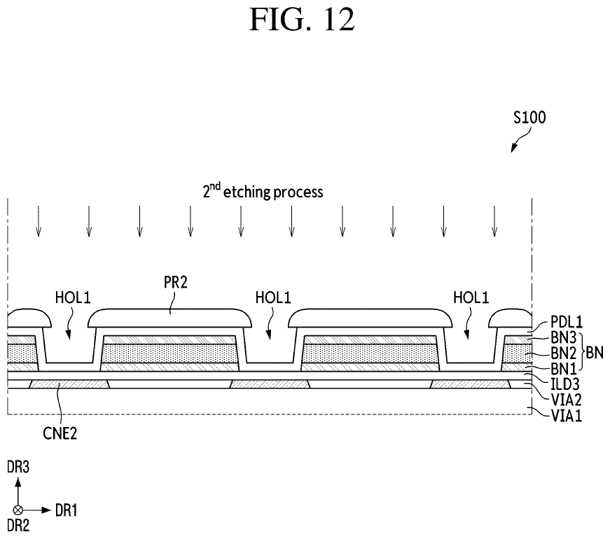

As illustrated in FIG. 12, the bank structure BN that does not overlap the photoresist PR1 may be removed at once and, thus, a hole HOL1 may be defined. The side surface of the first bank layer BN1, the side surface of the second bank layer BN2, and the side surface of the third bank layer BN3 that face the hole HOL1 may be disposed on the same line.

In the process, the third insulating layer ILD3 may be exposed in a portion overlapping the hole HOL1.

Although not shown in the drawing, the photoresist PR1 may be removed by an ashing process.

Next, the first element insulating layer PDL1 is formed on the bank structure BN. The first element insulating layer PDL1 may be entirely formed, and the first element insulating layer PDL1 may cover an entirety of the side surface of the first bank layer BN1, the side surface of the second bank layer BN2, and the side surface of the third bank layer BN3 that face the hole HOL1. In addition, the first element insulating layer PDL1 may cover the third insulating layer ILD3 in a portion overlapping the hole HOL1.

In the process, the process of forming the first element insulating layer PDL1 may be performed as a film forming process (e.g., deposition process) for forming at least one of the above-described inorganic materials.

Next, a photoresist PR2 is formed on the first element insulating layer PDL1, and a second etching process (2^{nd} etching process) is performed. A plurality of photoresists PR2 may be formed, and may be disposed in a portion that does not overlap the hole HOL1. In an embodiment, the second etching process may be performed as a dry etching process, for example. Redundant descriptions are omitted.

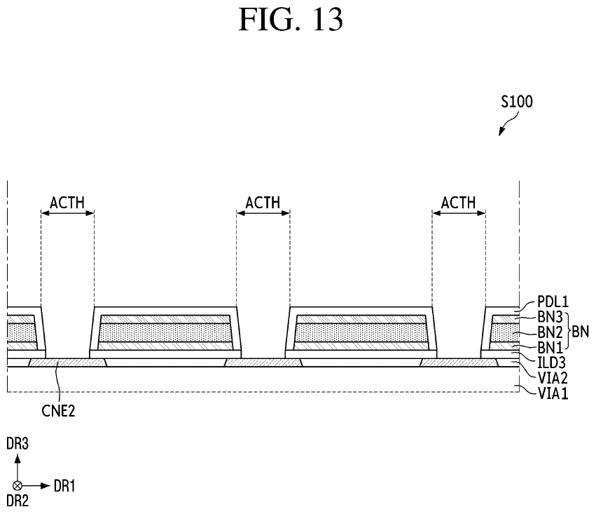

As shown in FIG. 13, in the process, the first element insulating layer PDL1 and the third insulating layer ILD3 that do not overlap the photoresist PR2 may be removed at once. Accordingly, the anode contact hole ACTH may be defined. In a portion overlapping the anode contact hole ACTH, the second connection electrode CNE2 may be exposed.

Although not shown in the drawing, the photoresist PR2 may be removed by an ashing process.

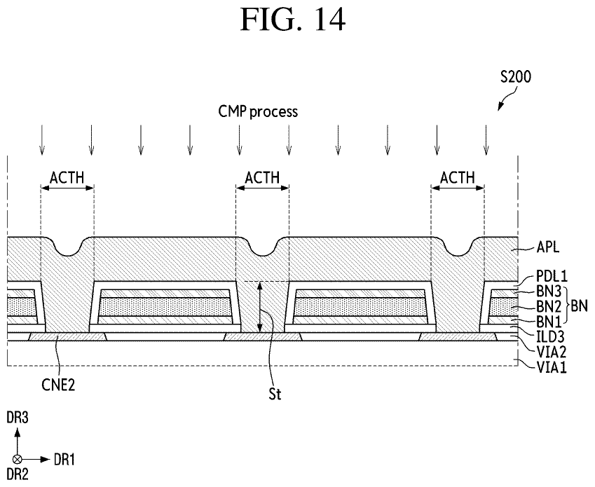

FIGS. 14 to 17 are cross-sectional views showing operation S200 of FIG. 10.

The operation S200 of forming the anode planarization layer and the anode electrode will be described with reference to FIGS. 14 to 17.

First, the anode planarization layer APL is formed on the first element insulating layer PDL1.

In the process, the process of forming the anode planarization layer APL may be performed as a film forming process (e.g., sputtering) for forming at least one of the above-described metal materials.

In the process, the anode planarization layer APL may be entirely in contact with and cover the second connection electrode CNE2 exposed in a portion overlapping the anode contact hole ACTH. Further, the anode planarization layer APL may be formed to have a height that completely fills a stepped portion St included in the anode contact hole ACTH in a portion overlapping the anode contact hole ACTH.

Next, a CMP process is performed. In an embodiment, the CMP process refers to a process of polishing and planarizing a surface having unevenness or curvature using a chemical/mechanical element, for example. In an embodiment, the CMP process performed in the process may be performed as a metal CMP process, for example.

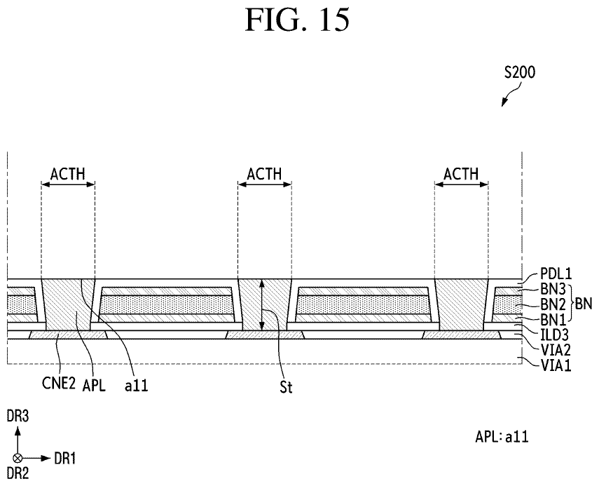

As illustrated in FIG. 15, in the process, a part of the anode planarization layer APL may be polished and removed, and the anode planarization layer APL may include the first surface a11 in a portion overlapping the anode contact hole ACTH. As described above, the first surface a11 of the anode planarization layer APL may have polished surface characteristics (e.g., a rough surface or a curved surface).

Due to the process, the anode planarization layer APL may fill the stepped portion St of the anode contact hole ACTH and, thus, the stepped portion St formed by the anode contact hole ACTH may be flattened.

Due to the process, a plurality of anode planarization layers APL may be formed, and the plurality of anode planarization layers APL may be spaced apart from each other. The anode planarization layer APL may not be disposed in a portion that does not overlap the anode contact hole ACTH.

The anode planarization layer APL may be separated from the bank structure BN by the first element insulating layer PDL1, and the bank structure BN may be disposed to surround the anode planarization layer APL.

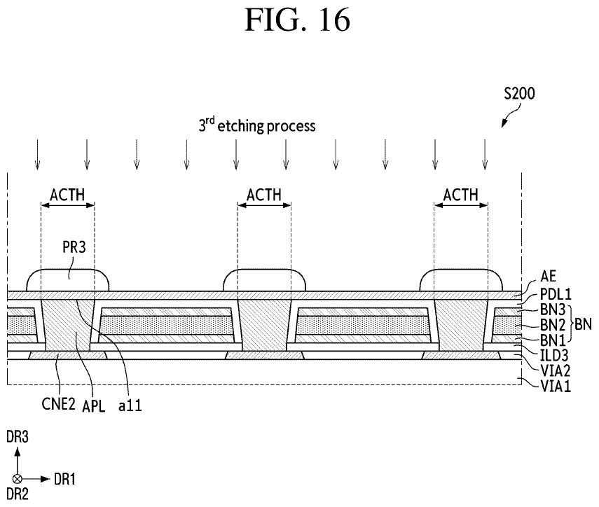

Next, as illustrated in FIG. 16, the anode electrode AE is formed on the first element insulating layer PDL1 and the anode planarization layer APL. The anode electrode AE may be entirely formed, and may completely cover the anode planarization layer APL.

In the process, the process of forming the anode electrode AE may be performed as a film forming process (e.g., sputtering) for forming at least one of the above-described metal materials.

Next, a photoresist PR3 is formed on the anode electrode AE, and a third etching process (3^{rd} etching process) is performed. In the process, a plurality of photoresist PR3 may be formed, and may be disposed in a portion overlapping the anode contact hole ACTH. In an embodiment, the third etching process may be performed as at least one of a dry etching process or a wet etching process, for example.

In an embodiment, the wet etching process may be performed using a liquid chemical solution such as a diluted hydrofluoric acid solution, a nitric acid solution, a tetramethylammonium hydroxide solution, a potassium hydroxide solution, or the like, for example.

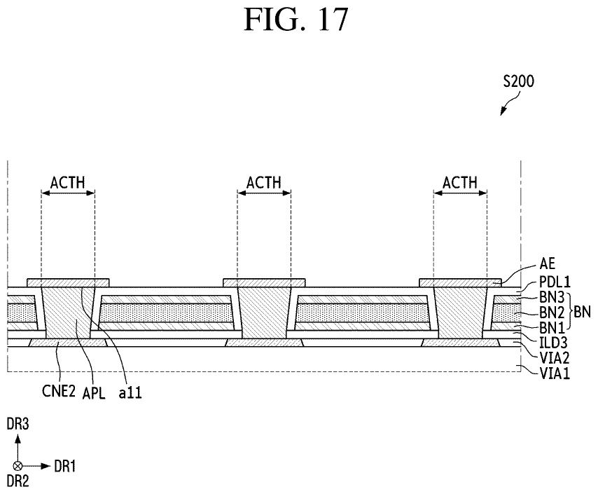

As shown in FIG. 17, due to the process, the anode electrode AE that does not overlap the photoresist PR3 may be removed and, thus, the anode electrode AE may be patterned. In the process, the first surface a11 of the anode planarization layer APL may be completely covered by the anode electrode AE.

Although not shown in the drawing, the photoresist PR3 may be removed by an ashing process.

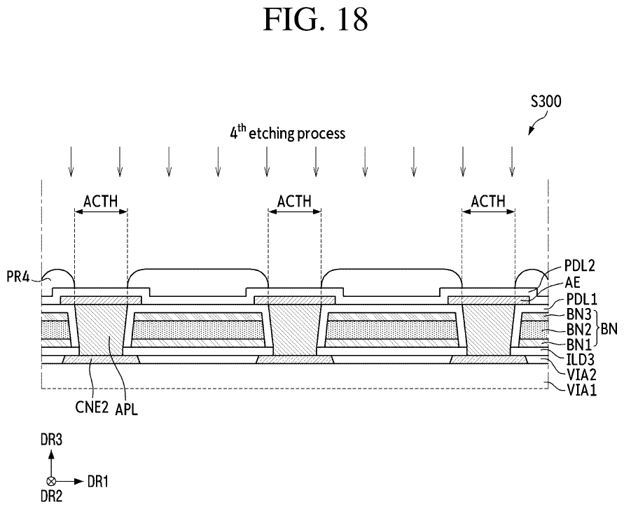

FIGS. 18 to 21 are cross-sectional views showing operation S300 of FIG. 10.

Referring to FIGS. 18 to 21, the operation S300 of forming a tip of a bank structure after a second element insulating layer that defines an opening is defined is described.

First, the second element insulating layer PDL2 is formed on the anode electrode AE and the first element insulating layer PDL1. In the process, the second element insulating layer PDL2 may cover an entirety of the anode electrode AE and the first element insulating layer PDL1.

Next, a photoresist PR4 is formed on the second element insulating layer PDL2, and a fourth etching process (4^{th} etching process) is performed. In the process, a plurality of photoresists PR4 may be formed, and may be disposed in a portion that does not overlap the anode contact hole ACTH. In an embodiment, the fourth etching process may be performed as a dry etching process, for example. Redundant descriptions are omitted.

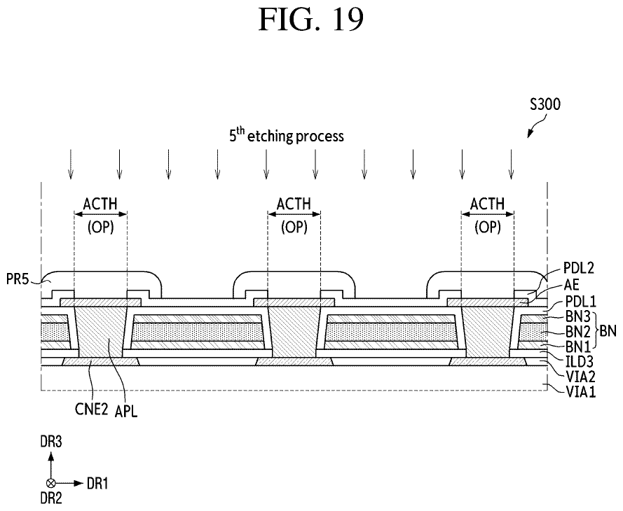

As illustrated in FIG. 19, in the process, the second element insulating layer PDL2 that does not overlap the photoresist PR4 may be removed and, thus, the opening OP may be formed. In other words, the opening OP may be defined by the second element insulating layer PDL2, and the second element insulating layer PDL2 may be disposed to surround the opening OP. The anode electrode AE may be exposed in a portion overlapping the opening OP.

Although not shown in the drawing, the photoresist PR4 may be removed by an ashing process.

Next, a photoresist PR5 is formed on the anode electrode AE and the second element insulating layer PDL2, and a fifth etching process (5^{th} etching process) is performed. In the process, a plurality of photoresists PR5 may be formed, and may be disposed in a portion overlapping the anode contact hole ACTH and/or the opening OP. In an embodiment, the fifth etching process may be performed as a dry etching process, for example. Redundant descriptions are omitted.

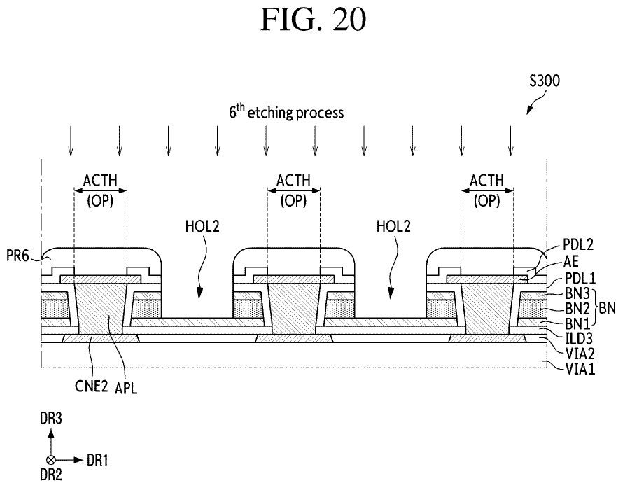

As illustrated in FIG. 20, in the process, the second element insulating layer PDL2, the first element insulating layer PDL1, the second bank layer BN2, and the third bank layer BN3 that do not overlap the photoresist PR5 may be removed at once and, thus, a hole HOL2 may be defined. The hole HOL2 may be defined in a portion that does not overlap the anode contact hole ACTH. The side surface of the second element insulating layer PDL2, the side surface of the first element insulating layer PDL1, the side surface of the second bank layer BN2, and the side surface of the third bank layer BN3 that face the hole HOL2 may be disposed on the same line. In other words, in the process, the second element insulating layer PDL2, the first element insulating layer PDL1, the second bank layer BN2, and the third bank layer BN3 that do not overlap the photoresist PR5 may be removed isotropically.

In the process, the first bank layer BN1 overlapping the hole HOL2 may be exposed.

Although not shown in the drawing, the photoresist PR5 may be removed by an ashing process.

Next, a photoresist PR6 is formed on the anode electrode AE and the second element insulating layer PDL2, and a sixth etching process (6^{th} etching process) is performed. In the process, a plurality of photoresists PR6 may be formed, and may be disposed in a portion overlapping the anode contact hole ACTH and/or the opening OP. The photoresist PR6 may cover an entirety of the top surfaces of the anode electrode AE and the second element insulating layer PDL2. In an embodiment, the sixth etching process may be performed as a wet etching process, for example. Redundant descriptions are omitted.

In the process, the second bank layer BN2 and the third bank layer BN3 including different metal materials may be different in etch selectivity. Specifically, in the same etching process, the third bank layer BN3 may have an etching resistance higher than that of the second bank layer BN2. In other words, in the same etching process, the second bank layer BN2 may include a material having an etching rate higher than that of the third bank layer BN3.

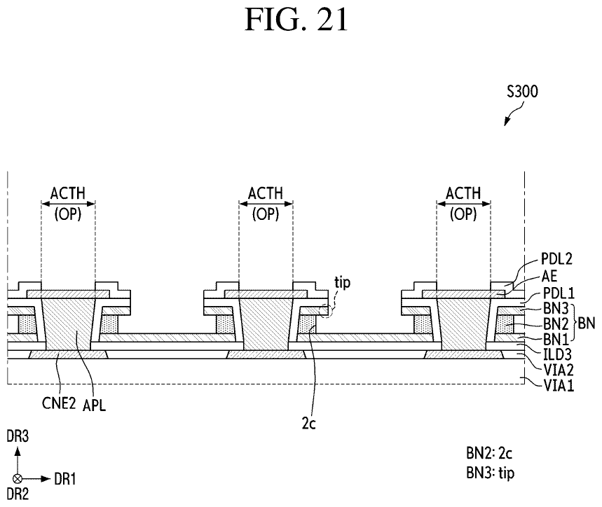

Therefore, as illustrated in FIG. 21, the third bank layer BN3 may include the tip protruding more in the first direction DR1 than the first side surface 2c of the second bank layer BN2. The first element insulating layer PDL1 and the second element insulating layer PDL2 may overlap the tip of the third bank layer BN3 in the third direction DR3. Redundant descriptions are omitted.

Although not shown in the drawing, the photoresist PR6 may be removed by an ashing process.

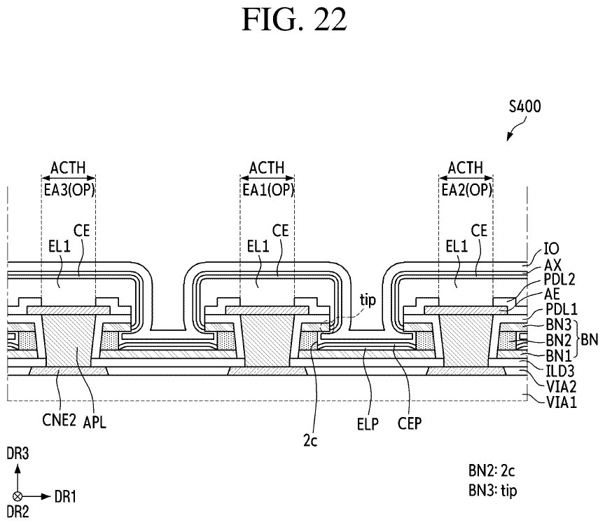

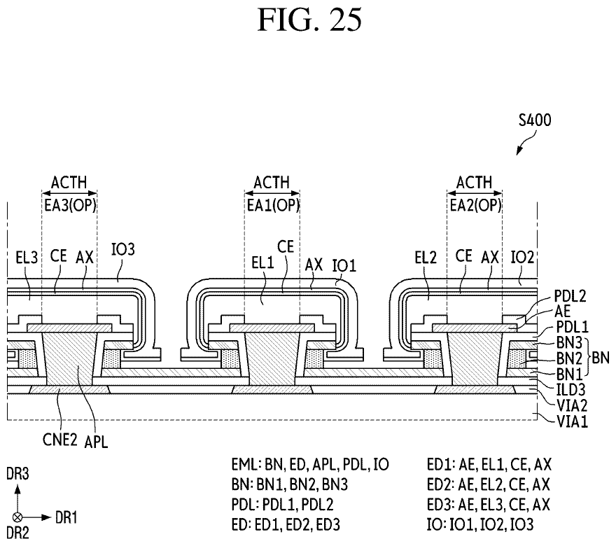

FIGS. 22 to 25 are cross-sectional views showing operation S400 of FIG. 10.

Referring to FIGS. 22 to 25, the operation S400 of forming a light-emitting layer, a cathode electrode, an auxiliary electrode, and an element inorganic layer on an anode electrode is described.

Next, the first light-emitting layer EL1, the cathode electrode CE, and the auxiliary electrode AX are deposited on the anode electrode AE to form the first light-emitting element ED1.

In the process, the process of forming the first light-emitting layer EL1 may be performed as a thermal deposition process. In the process, the material forming the first light-emitting layer EL1 may be formed not only on the anode electrode AE overlapping the first emission area EA1, but also on the anode electrode AE disposed in a portion overlapping the second emission area EA2 and the third emission area EA3. The first light-emitting layers EL1 disposed in portions overlapping the first to third emission areas EA1, EA2, and EA3 may be spaced apart from each other.

In addition, the material forming the first light-emitting layer EL1 may also be formed on the first bank layer BN1. The material forming the first light-emitting layer EL1 disposed on the anode electrode AE and the material forming the first light-emitting layer EL1 disposed on the first bank layer BN1 may be spaced apart from each other. The material forming the first light-emitting layer EL1 disposed on the first bank layer BN1 may be also referred to as an organic pattern ELP.

In the process, the process of forming the cathode electrode CE may be performed as a thermal deposition process or a sputtering process. The process of forming the cathode electrode CE may have step coverage characteristics higher than those of the process of forming the first light-emitting layer EL1. Thus, the cathode electrode CE may cover an entirety of the first light-emitting layer EL1.

In the process, the material forming the cathode electrode CE may be formed not only on the first light-emitting layer EL1 overlapping the first emission area EA1, but also on the first light-emitting layer EL1 disposed in a portion overlapping the second emission area EA2 and the third emission area EA3. The cathode electrodes CE disposed in portions overlapping the first to third emission areas EA1, EA2, and EA3 may be spaced apart from each other.

In addition, the material forming the cathode electrode CE may be formed not only on the first light-emitting layer EL1, but also on the organic pattern ELP. The material forming the cathode electrode CE disposed on the first light-emitting layer EL1 and the material forming the cathode electrode CE disposed on the organic pattern ELP may be spaced apart from each other. The material forming the cathode electrode CE formed on the first bank layer BN1 may be also referred to as an electrode pattern CEP.

In the process, the cathode electrode CE may contact the tip of the third bank layer BN3. Redundant descriptions are omitted.

In the process, the process of forming the auxiliary electrode AX may be performed as a sputtering process. The process of forming the auxiliary electrode AX may have step coverage characteristics higher than those of the process of forming the cathode electrode CE. Therefore, the auxiliary electrode AX may be entirely formed.

In other words, the material forming the auxiliary electrode AX may be formed not only on the cathode electrode CE but also on the electrode pattern CEP, and the auxiliary electrode AX formed on the cathode electrode CE and the auxiliary electrode AX formed on the electrode pattern CEP may be integrated.

In the process, the material forming the auxiliary electrode AX may contact the tip of the third bank layer BN3 and the first side surface 2c of the second bank layer BN2. Redundant descriptions are omitted.

Next, the element inorganic layer IO is formed on the auxiliary electrode AX. The element inorganic layer IO may cover the profile of the lower structure with a uniform thickness, and may cover an entirety of the auxiliary electrode AX.

In the process, the process of forming the element inorganic layer IO may be performed as a film forming process (e.g., deposition process) for forming at least one of the above-described inorganic materials.

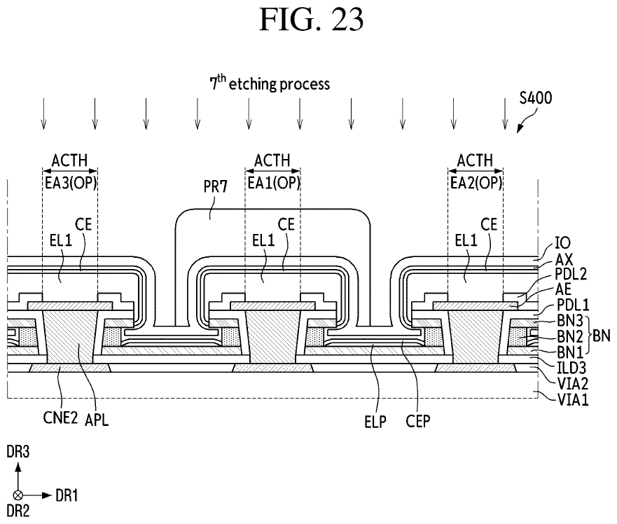

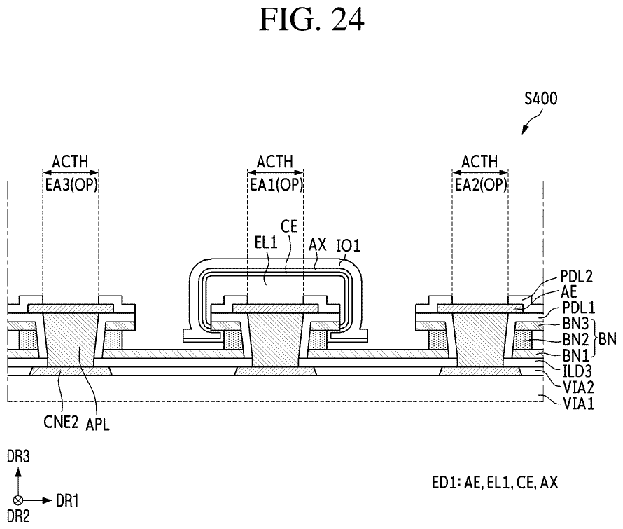

Next, as shown in FIGS. 23 and 24, a photoresist PR7 is formed in the first emission area EA1 and in a portion overlapping a peripheral part of the first emission area EA1, and a seventh etching process (7^{th} etching process) is performed using the photoresist PR7 as a mask.

In the process, the material forming the first light-emitting layer EL1, the material forming the cathode electrode CE, the material forming the auxiliary electrode AX, and the material forming the element inorganic layer IO that do not overlap the photoresist PR7 may be removed at once.

Accordingly, the anode electrode AE overlapping the second emission area EA2 and the anode electrode AE overlapping the third emission area EA3 may be exposed again, and the element inorganic layer IO may be formed in the form of the first element inorganic layer IO1.

In the process, both the organic pattern ELP and the electrode pattern CEP disposed on the first bank layer BN1 may be removed. Accordingly, the first element inorganic layer IO1 may be spaced apart from the first bank layer BN1 in the third direction DR3.

Accordingly, the first light-emitting element ED1 and the first element inorganic layer IO1 disposed in a portion overlapping the first emission area EA1 may be formed.

Next, the above-described process is repeated to form the second light-emitting layer EL2, the cathode electrode CE, the auxiliary electrode AX, and the element inorganic layer IO on the anode electrode AE overlapping the second emission area EA2. Due to the process, the second light-emitting element ED2 and the second element inorganic layer IO2 that overlap the second emission area EA2 may be formed.

In addition, the above-described process is repeated again to form the third light-emitting layer EL3, the cathode electrode CE, the auxiliary electrode AX, and the element inorganic layer IO on the anode electrode AE overlapping the third emission area EA3. Due to the process, the third light-emitting element ED3 and the third element inorganic layer IO3 that overlap the third emission area EA3 may be formed.

Accordingly, the display element layer EML overlapping the anode contact hole ACTH illustrated in FIG. 5 may be formed. Redundant descriptions are omitted.

In the display device 10 of an embodiment, the third bank layer BN3 includes the tip, so that the first light-emitting layer EL1, the second light-emitting layer EL2, and the third light-emitting layer EL3 that are spaced apart from each other may be formed in portions overlapping the first to third emission areas EA1, EA2, and EA3 without a separate fine metal mask.

Further, in the display device 10 of an embodiment, the third bank layer BN3 includes the tip, so that the cathode electrodes CE spaced apart from each other may be formed in portions overlapping the first to third emission areas EA1, EA2, and EA3 without a separate fine metal mask. Accordingly, the display device 10 of an embodiment may have ease of fabrication.

In addition, the display device 10 of an embodiment includes the anode planarization layer APL that fills the anode contact hole ACTH in a portion overlapping the anode contact hole ACTH, thereby flattening the stepped portion included in the anode planarization layer APL. Accordingly, the anode electrode AE may be formed to have one flat surface and, thus, the first to third light-emitting layers EL1, EL2, and EL3 may also be formed with a uniform thickness. Accordingly, the display device 10 may solve reliability defects (e.g., light-emitting layer shadow defects). Other redundant descriptions are omitted.

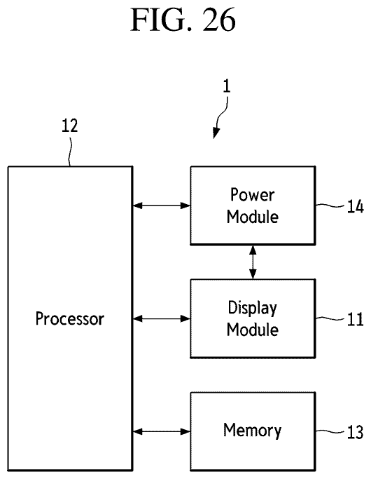

FIG. 26 is a block diagram of an embodiment of an electronic device.

Referring to FIG. 26 in addition to FIGS. 1 to 25, the display device 10 in an embodiment may be applied to various electronic devices. An electronic device 1 in an embodiment may include the above-described display device 10, and may further include, in addition to the display device 10, a module or device having other additional functions.

The electronic device 1 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), or a controller.

The memory 13 may store data information desired for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power desired for the operation of the electronic device 1.

At least one of the components of the electronic device 1 described above may be included in the display device in the embodiments described above. Further, some of individual modules functionally included in one module may be included in the display device and some others may be provided separately from the display device. In an embodiment, the display device may include the display module 11, and the processor 12, the memory 13, and the power module 14 may be provided in the form of other devices in the electronic device 1 other than the display device, for example.

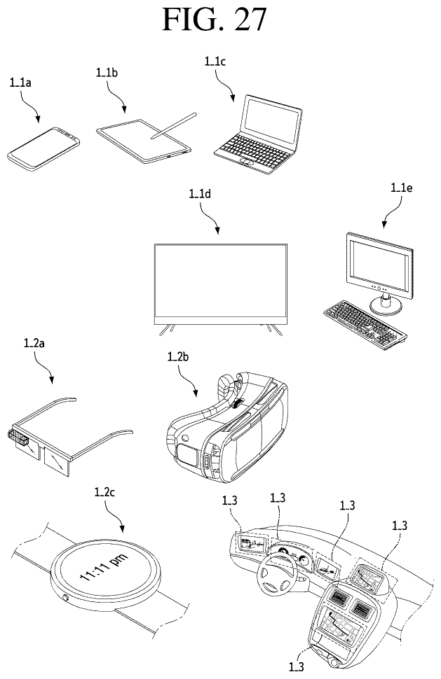

FIG. 27 is schematic views of embodiments of electronic devices.

Referring to FIG. 27, various electronic devices to which the display device 10 in embodiments is applied may include not only an image display electronic device such as a smartphone 1_1a, a tablet PC 1_1b, a laptop 1_1c, a television (“TV”) 1_1d, and a desk monitor 1_1e, but also a wearable electronic device including a display module, such as smart glasses 1_2a, a head mounted display 1_2b, a smart watch 1_2c, or the like, a vehicle electronic device 1_3 including a display module, such as a center information display (“CID”) placed on a dashboard, a center fascia, and an instrument panel of a car, a room mirror display, or the like.

Embodiments of the disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a substrate comprising an emission area and a non-emission area;
a bank structure which is disposed on the emission area of the substrate and has an overhang structure and through which an anode contact hole overlapping the emission area penetrates;
a connection electrode disposed between the substrate and the bank structure in a portion overlapping the anode contact hole;
a first element insulating layer disposed on the bank structure, overlapping the anode contact hole and covering a side surface of the bank structure;
an anode electrode disposed on the first element insulating layer;
an anode planarization layer disposed between the connection electrode and the anode electrode in a portion overlapping the anode contact hole; and
a second element insulating layer covering an edge of the anode electrode, defining an opening, and in contact with the first element insulating layer.

2. The display device of claim 1, wherein the bank structure comprises:
a first bank layer;
a second bank layer disposed on the first bank layer; and
a third bank layer including a tip protruding toward the non-emission area more than a first side surface of the second bank layer,
wherein the anode planarization layer overlaps the anode contact hole and penetrates the first bank layer, the second bank layer, and the third bank layer.

3. The display device of claim 2, wherein the anode planarization layer is spaced apart from the first bank layer, the second bank layer, the third bank layer while the first element insulating layer is interposed between the anode planarization layer and the first to third bank layers.

4. The display device of claim 2, further comprising:
a first light-emitting layer disposed on the anode electrode and entirely covering the second element insulating layer;
a cathode electrode disposed on the first light-emitting layer; and
an auxiliary electrode disposed on the cathode electrode and in contact with the tip of the third bank layer.

5. The display device of claim 4, wherein the auxiliary electrode contacts the first side surface of the second bank layer, and
in a portion overlapping the non-emission area, the auxiliary electrode is spaced apart from the first bank layer in a direction perpendicular to the substrate.

6. The display device of claim 1, wherein the anode planarization layer contacts the anode electrode and the connection electrode, and
the anode planarization layer is electrically connected to the anode electrode and the connection electrode.

7. The display device of claim 6, further comprising:
a transistor disposed between the substrate and the connection electrode,
wherein the anode electrode is connected to the transistor through the anode planarization layer and the connection electrode.

8. The display device of claim 1, wherein the anode planarization layer completely fills the anode contact hole.

9. The display device of claim 1, wherein the anode planarization layer includes a transparent conductive material.

10. The display device of claim 1, wherein the anode planarization layer comprises a first surface facing the anode electrode, and
the first surface is completely covered by the anode electrode.

11. The display device of claim 1, wherein in a plan view, the first element insulating layer exposes the anode planarization layer, and
in the plan view, the first element insulating layer completely surrounds the anode planarization layer.

12. The display device of claim 11, wherein in the plan view, the bank structure is spaced apart from the anode planarization layer while the first element insulating layer is interposed between the bank structure and the anode planarization layer, and
in the plan view, the bank structure completely surrounds the anode planarization layer.

13. A method for fabricating a display device, the method comprising:
defining an anode contact hole penetrating a bank structure and a first element insulating layer;
forming an anode planarization layer and an anode electrode;
forming a tip of the bank structure after forming a second element insulating layer defining an opening; and
forming a light-emitting layer, a cathode electrode, an auxiliary electrode, and an element inorganic layer on the anode electrode.

14. The method of claim 13, wherein in the forming the anode planarization layer and the anode electrode,
a part of the anode planarization layer is removed by performing a chemical mechanical polishing process,
the anode planarization layer comprises a first surface in contact with the anode electrode, and
the first surface comprises a surface polished by the chemical mechanical polishing process.

15. An electronic device comprising:
a display device comprising:
a substrate comprising an emission area and a non-emission area,
a bank structure which is disposed on the emission area of the substrate and has an overhang structure and through which an anode contact hole overlapping the emission area penetrates;
a connection electrode disposed between the substrate and the bank structure in a portion overlapping the anode contact hole;
a first element insulating layer disposed on the bank structure, overlapping the anode contact hole and covering a side surface of the bank structure;
an anode electrode disposed on the first element insulating layer;
an anode planarization layer disposed between the connection electrode and the anode electrode in a portion overlapping the anode contact hole;
a second element insulating layer covering an edge of the anode electrode, defining an opening, and in contact with the first element insulating layer; and
at least one of a display module, a processor, a memory, and a power module connected to the display device.

16. The electronic device of claim 15, wherein the bank structure comprises:
a first bank layer;
a second bank layer disposed on the first bank layer; and
a third bank layer including a tip protruding toward the non-emission area more than a first side surface of the second bank layer,
wherein the anode planarization layer penetrates the first bank layer, the second bank layer, and the third bank layer while overlapping the anode contact hole.

17. The electronic device of claim 16, wherein the anode planarization layer is spaced apart from the first bank layer, the second bank layer, the third bank layer while the first element insulating layer is interposed between the anode planarization layer and the first to third bank layers.

18. The electronic device of claim 16, further comprising:
a first light-emitting layer disposed on the anode electrode and entirely covering the second element insulating layer;
a cathode electrode disposed on the first light-emitting layer; and
an auxiliary electrode disposed on the cathode electrode and in contact with the tip of the third bank layer.

19. The electronic device of claim 15, wherein the anode planarization layer completely fills the anode contact hole.

20. The electronic device of claim 15, further comprising:
a transistor disposed between the substrate and the connection electrode,
wherein the anode electrode is connected to the transistor through the anode planarization layer and the connection electrode.
